(19) United States
(12) Patent Application Publication
(10) Pub. No.: US 2026/0181880 A1
(43) Pub. Date: Jun. 25, 2026

(54) SEMICONDUCTOR DEVICES

(71) Applicant: Samsung Electronics Co., Ltd., Suwon-si (KR)

(72) Inventors: Seungbo Ko, Suwon-si (KR); Kiseok Lee, Suwon-si (KR); Jongmin Kim, Suwon-si (KR); Chahee Kim, Suwon-si (KR); Taehoon Kim, Suwon-si (KR)

(21) Appl. No.: 19/363,080

(22) Filed: Oct. 20, 2025

(30) Foreign Application Priority Data
Dec. 24, 2024 (KR) 10-2024-0195285

(51) Int. Cl. H10B 12/00

(52) U.S. Cl. CPC H10B 12/50; H10B 12/315

(57) ABSTRACT

A semiconductor device includes a substrate including an active region extending in a first direction, a gate structure extending in a second direction intersecting the active region on the substrate, a source/drain region in a recessed region of the active region on at least one side of the gate structure, a first conductive structure connected to the source/drain region, and a first contact spacer. The first conductive structure includes a first interconnection portion, a first via portion extending from a lower surface of the first interconnection portion, and a first contact barrier layer on a lower surface of the first interconnection portion and a side surface and a lower surface of the first via portion. The first contact spacer extends along at least a portion of a side surface of the first via portion below the first interconnection portion.

### CROSS-REFERENCE TO PRIORITY APPLICATION

This application claims priority to Korean Patent Application No. 10-2024-0195285, filed on Dec. 24, 2024, the disclosure of which is incorporated herein by reference in its entirety.

### BACKGROUND

Example embodiments of the present disclosure relate to a semiconductor device, such as a semiconductor device including a contact plug connected to a peripheral transistor and a conductive structure on the contact plug.

Research into reducing sizes of elements included in a semiconductor device and improving performance has been conducted. For example, for DRAM (Dynamic Random Access Memory), research has been conducted into reliably and stably forming elements having reduced size, but as the size of elements decreases, performance of a semiconductor device tends to correspondingly deteriorate.

### SUMMARY

Example embodiments of the present disclosure provide semiconductor devices having improved reliability.

According to an example embodiment of the present disclosure, a semiconductor device includes a first structure including a memory region, and a second structure vertically overlapping the first structure and including a peripheral circuit region vertically overlapping the memory region. The first structure includes memory cells in the memory region, and each including a vertical channel transistor and a data storage structure, and a cell routing interconnection structure connected to the memory cells. The second structure includes a peripheral transistor including a gate structure and a source/drain region, a first contact plug connected to the source/drain region on the source/drain region, and a first conductive structure connected to the first contact plug on the first contact plug. The first conductive structure includes a first via portion in contact with the first contact plug and a first interconnection portion extending from the first via portion on the first via portion, where a width in a first direction of the first via portion is smaller than a width in the first direction of the first interconnection portion.

According to an example embodiment of the present disclosure, a semiconductor device includes a substrate including an active region extending in a first direction, a gate structure extending in a second direction intersecting the active region on the substrate, a source/drain region in a recessed region of the active region on at least one side of the gate structure, a first conductive structure connected to the source/drain region on the source/drain region, and a first contact spacer. The first conductive structure includes a first interconnection portion, a first via portion extending from a lower surface of the first interconnection portion, and a first contact barrier layer on a lower surface of the first interconnection portion and a side surface and a lower surface of the first via portion. The first contact spacer extends along at least a portion of the side surface of the first via portion below the first interconnection portion, relative to the substrate.

According to an example embodiment of the present disclosure, a semiconductor device includes a first structure having a memory region, and a second structure vertically overlapping the first structure and including a peripheral circuit region vertically overlapping the memory region. The first structure includes memory cells in the memory region, with each including a vertical channel transistor and a data storage structure, and a cell routing interconnection structure connected to the memory cells. The second structure includes a substrate including an active region extending in a first direction, a peripheral gate structure extending in a second direction intersecting the active region on the substrate, a source/drain region in a recessed region of the active region on at least one side of the peripheral gate structure, a first contact plug connected to the source/drain region on the source/drain region, a second contact plug connected to the peripheral gate structure on the peripheral gate structure, a first conductive structure connected to the first contact plug on the first contact plug, a second conductive structure connected to the second contact plug on the second contact plug; a first contact spacer, and a second contact spacer. The first conductive structure includes a first via portion in contact with the first contact plug and a first interconnection portion extending from the first via portion in the second direction on the first via portion. The second conductive structure includes a second via portion in contact with the second contact plug, and a second interconnection portion extending from the second via portion in the second direction and spaced apart from the first interconnection portion in the first direction on the second via portion. The first contact spacer is between the first contact plug and the first interconnection portion of the first conductive structure and is on a side surface of the first via portion. The second contact spacer is between the second contact plug and the second interconnection portion of the second conductive structure and is on a side surface of the second via portion.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a perspective diagram illustrating a semiconductor device according to an example embodiment of the present disclosure;

FIG. 1B is a perspective diagram illustrating a bank of the semiconductor device illustrated in FIG. 1A;

FIG. 1C is a circuit diagram illustrating a first structure in a memory cell array region of the semiconductor device illustrated in FIG. 1A;

FIG. 2A is a plan diagram illustrating a peripheral circuit and interconnection structures connected to the peripheral circuit of the semiconductor device illustrated in FIG. 1A;

FIG. 2B is a plan diagram illustrating a portion of elements of the semiconductor device illustrated in FIG. 2A;

FIG. 2C is a plan diagram illustrating a portion of elements of the semiconductor device illustrated in FIG. 2A;

FIG. 3 is a cross-sectional diagram illustrating the semiconductor device illustrated in FIG. 2A taken along line I-I′;

FIG. 4 is a cross-sectional diagram illustrating the semiconductor device illustrated in FIG. 2A taken along line II-II′;

FIG. 5 is a cross-sectional diagram illustrating a second structure of the semiconductor device illustrated in FIG. 2A taken along line III-III';

FIG. 6 is an enlarged diagram illustrating region “A” of the semiconductor device illustrated in FIG. 3;

FIG. 7 is an enlarged diagram illustrating region “B” of the semiconductor device illustrated in FIG. 4;

FIGS. 8A, 8B, 8C, 8D, and 8E are enlarged diagrams illustrating region “A” of the semiconductor device illustrated in FIG. 3 according to other example embodiments of the present disclosure;

FIGS. 9A, 9B, 9C, 9D, 9E, 9F, 9G, 9H, and 9I are diagrams illustrating a method of manufacturing a semiconductor device according to an example embodiment of the present disclosure;

FIGS. 10A, 10B, 10C, 10D, 10E, 10F, and 10G are diagrams illustrating a method of manufacturing a semiconductor device according to another example embodiment of the present disclosure;

FIGS. 11A, 11B, and 11C are diagrams illustrating a method of manufacturing a semiconductor device according to another example embodiment of the present disclosure; and

FIGS. 12A, 12B, 12C, 12D, 12E, and 12F are diagrams illustrating a method of manufacturing a semiconductor device according to another example embodiment of the present disclosure.

### DETAILED DESCRIPTION OF EMBODIMENTS

Hereinafter, embodiments of the present disclosure will be described as follows with reference to the accompanying drawings.

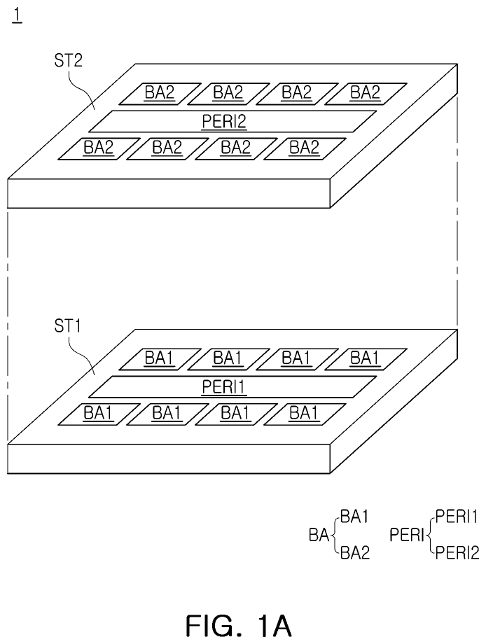

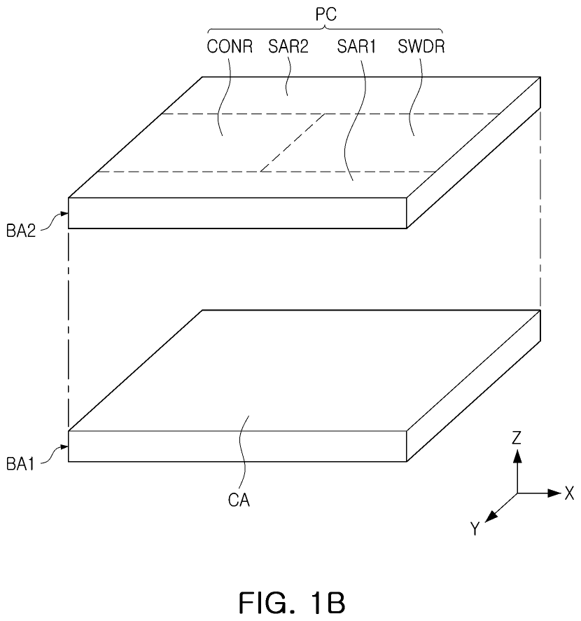

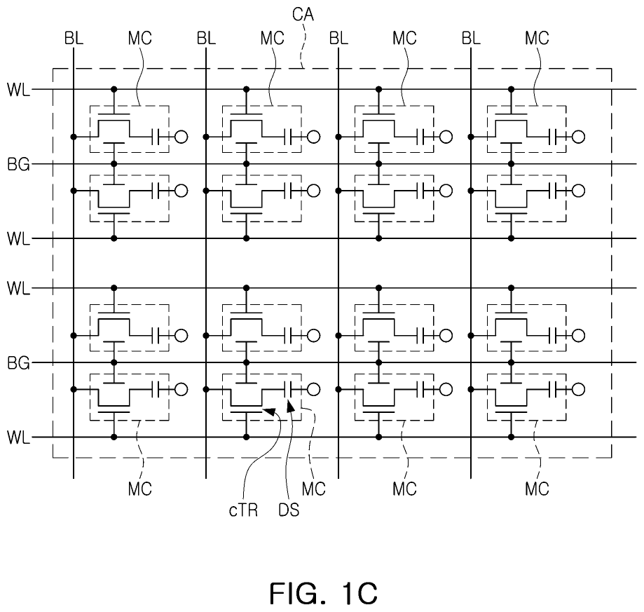

FIG. 1A is a perspective diagram illustrating a semiconductor device according to an example embodiment. FIG. 1B is a perspective diagram illustrating a bank of the semiconductor device illustrated in FIG. 1A. FIG. 1C is a circuit diagram illustrating a first structure in a memory cell array region of the semiconductor device illustrated in FIG. 1A.

Referring to FIGS. 1A and 1B, a semiconductor device 1 may include a first structure ST1 and a second structure ST2 vertically overlapping the first structure ST1. The second structure ST2 may be disposed on the first structure ST1.

The first structure ST1 may be configured as a first chip structure including memory cells, and the second structure ST2 may be configured as a second chip structure including peripheral circuits which may operate the memory cells. The first structure ST1 and the second structure ST2 may be bonded to each other by a bonding process such as a wafer bonding process. Accordingly, the first structure ST1 may be in contact with and bonded to the second structure ST2.

The semiconductor device 1 may include a plurality of banks BA and peripheral circuit regions PERI. The peripheral circuit region PERI may include a first peripheral region PERI1 in the first structure ST1 and a second peripheral region PERI2 in the second structure ST2. The peripheral circuit region PERI may be configured as a peripheral circuit region in which peripheral circuits for input and output of data or commands, or input of power/ground, are disposed.

Each of the plurality of banks BA may include a first bank region BA1 in the first structure ST1 and a second bank region BA2 in the second structure ST2.

Referring to FIGS. 1B and 1C, the first bank region BA1 in the first structure ST1 may include memory cell array regions CA. The memory cell array regions CA may include memory cells. In example embodiments, the memory cell array region CA may be referred to as a memory region.

The memory cell array regions CA may be arranged in the first direction (X-direction) and the second direction (Y-direction). Each of the memory cell array regions CA may include memory cells MC arranged in the first direction (X-direction) and the second direction (Y-direction), wordlines WL connected to the memory cells MC and extending in the first direction X, and bitlines BL connected to the memory cells MC and extending in the second direction Y.

Each of the memory cells MC may include a cell transistor cTR and a data storage structure DS working as data storage. In a memory such as DRAM, the data storage structure DS may be configured as a cell capacitor which may store data.

Each of the memory cell array regions CA may further include back gate lines BG. Each of the back gate lines BG may be disposed between a pair of wordlines WL adjacent to each other in the second direction (Y-direction) among the wordlines WL. Each of the back gate lines BG may be disposed between channel regions of the cell transistors cTR.

The second bank region BA2 in the second structure ST2 may include peripheral circuit regions PC. The peripheral circuit regions PC may be arranged in the first direction (X-direction) and the second direction (Y-direction). The peripheral circuit regions PC may overlap the memory cell array regions CA in the vertical direction (Z-direction). Each of the peripheral circuit regions PC may include a sense amplifier region SAR1 and SAR2, a sub-wordline driver region SWDR, and an inner peripheral region CONR. In each of the peripheral circuit regions PC, the sense amplifier regions SAR1 and SAR2 may include a first sense amplifier region SAR1 and a second sense amplifier region SAR2 spaced apart from each other in the second direction (Y-direction). In each of the peripheral circuit regions PC, the sub-wordline driver region SWDR and the inner peripheral region CONR may be disposed between the first sense amplifier region SAR1 and the second sense amplifier region SAR2. In each of the peripheral circuit regions PC, the inner peripheral region CONR may include a control circuit which may control the sense amplifiers of the sense amplifier regions SAR1 and SAR2 and the sub-wordline driver of the sub-wordline driver region SWDR.

The first direction (X-direction) and the second direction (Y-direction) may be perpendicular to each other. The first direction (X-direction) and the second direction (Y-direction) may be referred to as the horizontal direction, and the third direction (Z-direction) may be referred to as the vertical direction.

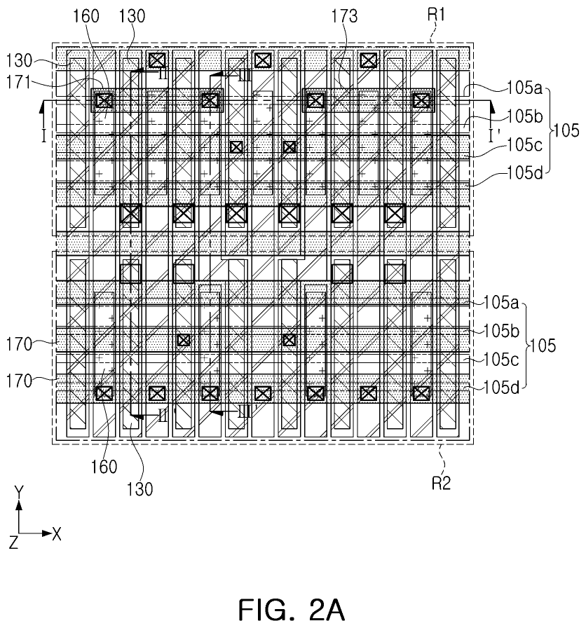

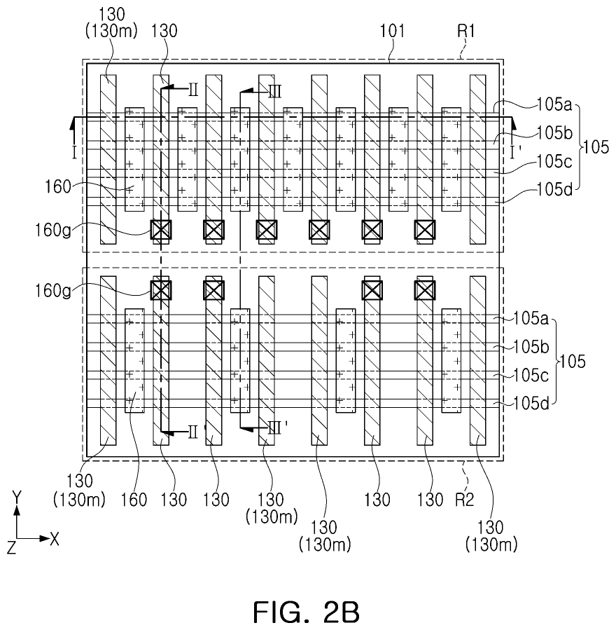

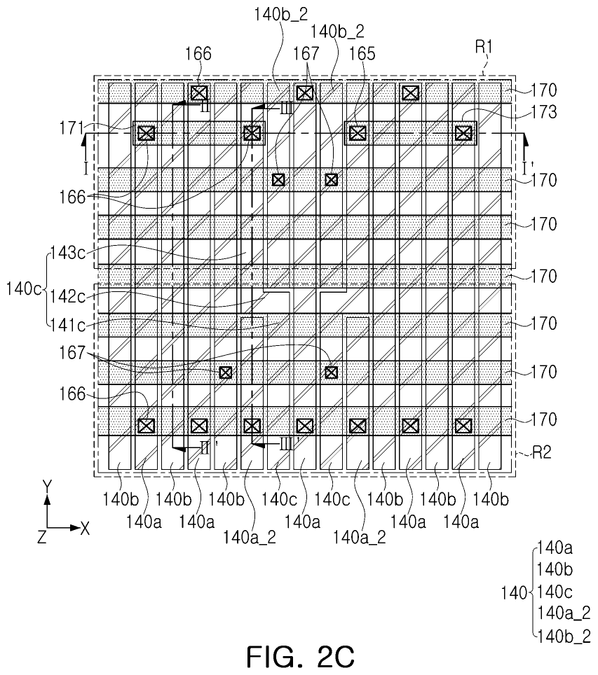

FIG. 2A is a plan diagram illustrating a peripheral circuit and interconnection structures connected to the peripheral circuit of the semiconductor device illustrated in FIG. 1A. FIG. 2B is a plan diagram illustrating a portion of elements of the semiconductor device illustrated in FIG. 2A. FIG. 2C is a plan diagram illustrating the other portion of elements of the semiconductor device illustrated in FIG. 2A.

FIG. 2A illustrates a layout of the peripheral circuit of the second structure ST2 of the semiconductor device 1 in FIG. 1A and the interconnection structures connected to the peripheral circuit. FIG. 2B illustrates a layout of the substrate 101 including the active regions, the first contact plugs 160, and the gate electrodes 130. FIG. 2C illustrates a layout of the conductive structures 140 and the interconnection structures 170, 171, and 173 connected to the peripheral circuit region.

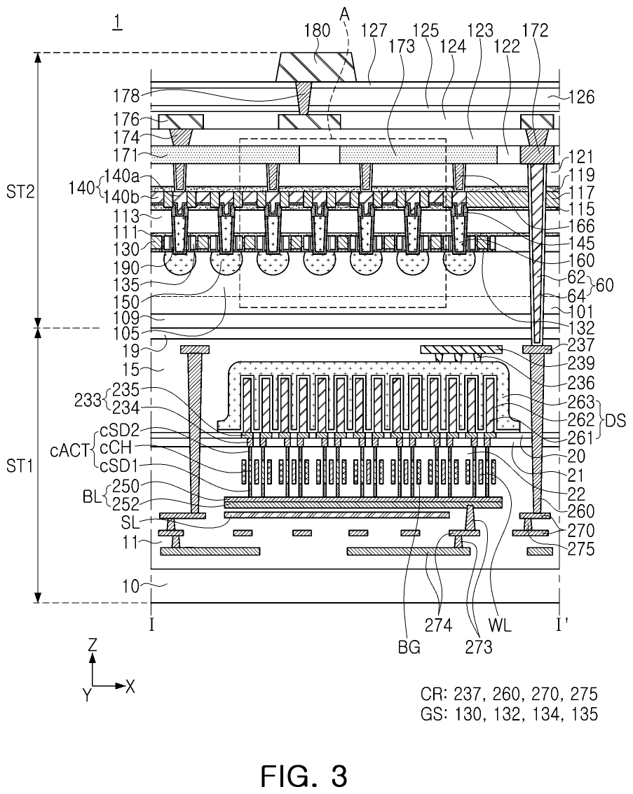

Referring to FIGS. 2A, 2B, and 2C, a semiconductor device 1 may include a substrate 101 including active regions 105, a second bonding adhesive layer 109 disposed below the substrate 101, gate electrodes 130 disposed on the substrate 101, first contact plugs 160 disposed between the gate electrodes 130 and connected to source/drain regions (e.g., a source/drain region 150 in FIG. 3), second contact plugs 160g connected to the gate electrodes 130, conductive structures 140 connected to the first and second contact plugs 160 and 160g, and interconnection structures 170, 171, and 173 connected to the conductive structures 140.

The substrate 101 may have an upper surface extending in the first direction (X-direction) and the second direction (Y-direction). The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

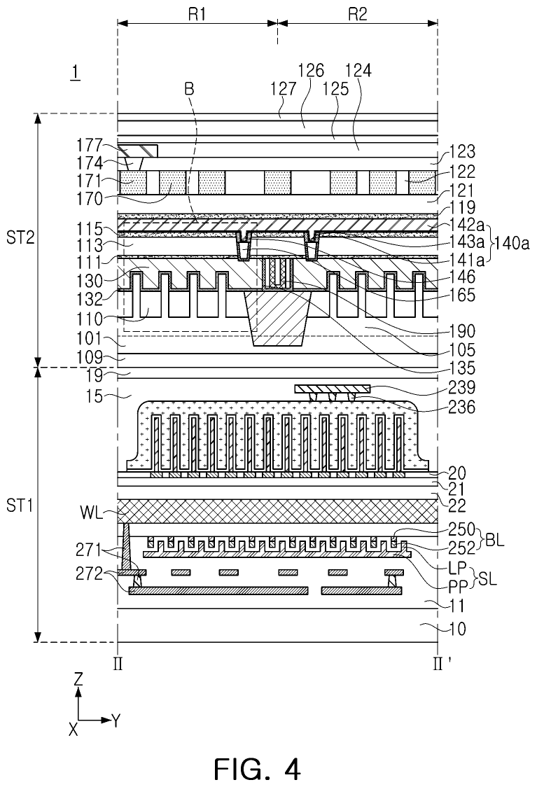

The substrate 101 may include active regions 105 disposed thereon. The active regions 105 may have a fin structure. The active regions 105 may be defined by a device isolation layer (e.g., the device isolation layer 110 in FIG. 4) in the substrate 101 and may extend in the first direction (X-direction). However, the present disclosure fully contemplates that the active region 105 may be configured separately from the substrate 101.

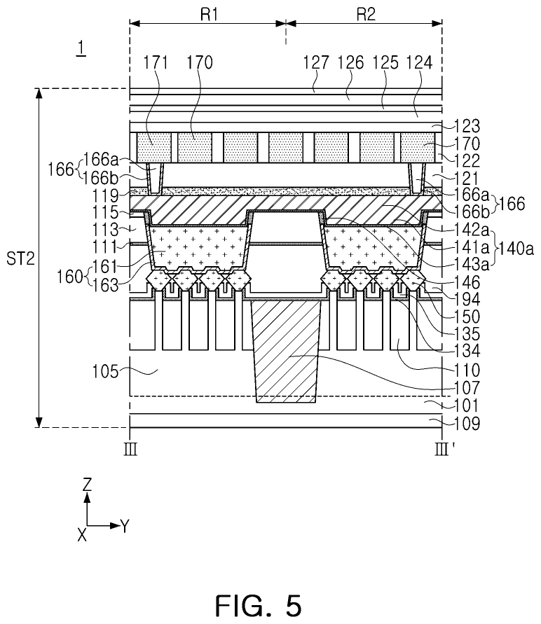

The substrate 101 may include a first region R1 and a second region R2 spaced apart from the first region R1 in the second direction (Y-direction). In an example, each of the first region R1 and the second region R2 may include active regions 105 extending in the first direction. For example, each of the first region R1 and the second region R2 may have first to fourth active regions 105a-105d disposed. The first to fourth active regions 105a-105d disposed in the first region R1 and the first to fourth active regions 105a-105d disposed in the second region R2 may be partitioned by a trench structure (e.g., the trench structure 107 in FIG. 5).

The gate electrodes 130 may intersect with the active regions 105 and may extend in the second direction (Y-direction) on the active regions 105. The active regions 105 intersecting with the gate electrodes 130 may form a functional channel region of the peripheral transistor.

The gate electrodes 130 disposed in the first region R1 and the second region R2, respectively, may extend in the second direction (Y-direction) and may be spaced apart from each other in the first direction (X-direction).

Among the gate electrodes 130, dummy gate electrodes 130m not electrically connected may be included. For example, among the gate electrodes 130 disposed in the first region R1, the gate electrodes disposed on both ends in the first direction (X-direction) may be dummy gate electrodes 130m . The dummy gate electrodes 130m may be disposed between the gate electrodes 130 electrically connected to each other among the gate electrodes 130 disposed in the second region R2.

The second contact plugs 160g may be disposed on the gate electrodes 130 and may be electrically connected to the gate electrodes 130. The gate electrode 130 not connected to the second contact plug 160g may be referred to as a dummy gate electrode 130m . The second contact plug 160g may not overlap the active regions 105.

The first contact plugs 160 may be disposed between the gate electrodes 130 and may be connected to the source/drain regions (e.g., the source/drain region 150 in FIG. 3. The first contact plugs 160 disposed in the first and second regions R1 and R2, respectively, may extend in the second direction (Y-direction) and may be spaced apart from each other in the first direction (X-direction). Each of the first contact plugs 160 may be disposed throughout the first to fourth active regions 105a-105d on the first to fourth active regions 105a-105d. In an example, the first contact plugs 160 may be disposed between the gate electrodes 130 disposed in the first region R1. The first contact plug 160 may be disposed between the gate electrodes 130 disposed in the second region R2, and the first contact plug 160 may not be disposed between a portion of the gate electrodes 130 disposed in the second region R2. In an example, a length of each of the first contact plugs 160 in the second direction (Y-direction) may be less than a length of each of the gate electrodes 130 in the second direction (Y-direction).

The conductive structures 140 may be disposed on the first and second contact plugs 160 and 160g. The conductive structures 140 may extend in the second direction (Y-direction) throughout the first and second regions R1 and R2, and may be spaced apart from each other in the first direction (X-direction).

The conductive structures 140 may include first conductive structures 140a and second conductive structures 140b. The first conductive structures 140a and the second conductive structures 140b may be disposed alternately in the first direction (X-direction).

Each of the first conductive structures 140a may be disposed throughout the first and second regions R1 and R2, and may overlap the first contact plugs 160 disposed in the first and second regions R1 and R2 in the vertical direction (Z-direction). The second conductive structures 140b may be disposed throughout the first and second regions R1 and R2, and may overlap the gate electrodes 130 disposed in the first and second regions R1 and R2 in the vertical direction (Z-direction).

Referring to FIG. 2C, the conductive structures 140 may further include third conductive structures 140c and fourth conductive structures 140a_2 and 140b_2. Each of the third conductive structures 140c may be disposed between one of the first conductive structures 140a and the second conductive structure 140b.

The third conductive structure 140c may be disposed throughout the first and second regions R1 and R2, and may include a first extension portion 141c overlapping one of the first contact plugs 160 disposed in the first region R1 and extending in the second direction (Y-direction), a bent portion 142c extending from the first extension portion 141c and extending in the first direction (X-direction), and a second extension portion 143c extending from the bent portion 142c and overlapping the dummy gate electrode 130m of the second region R2 and extending in the second direction (Y-direction).

The fourth conductive structures 140a_2 and 140b_2 may include 4-1 conductive structures 140a_2 disposed in the second region R2 and 4-2 conductive structures 140b_2 disposed in the first region R1. The 4-1 conductive structure 140a_2 may be spaced apart from the first extension portion 141c of the third conductive structure 140c in the first direction (X-direction) and the second extension portion 143c in the second direction (Y-direction), and may overlap the first contact plug 160. The 4-2 conductive structure 140b_2 may be spaced apart from the second extension portion 143c of the third conductive structure 140c in the first direction (X-direction) and the first extension portion 141c in the second direction (Y-direction), and may overlap the gate electrode 130.

Interconnection structures 170, 171, and 173 may include first interconnection structures 170 and second interconnection structures 171 and 173. The first interconnection structures 170 may be disposed on the conductive structures 140 and may extend in the first direction (X-direction) and may be spaced apart from each other in the second direction (Y-direction). In an example, the first interconnection structures 170 may be disposed on the conductive structures 140 in a direction intersecting the conductive structures 140. The second interconnection structures 171 and 173 may be disposed between the first interconnection structures 170 spaced apart from each other in the second direction (Y-direction). Each of the second interconnection structures 171 and 173 disposed between the first interconnection structures 170 may extend in the first direction (X-direction). The second interconnection structures 171 and 173 may include a 2-1 interconnection structure 171 and a 2-2 interconnection structure 173 spaced apart from the 2-1 interconnection structure 171 in the first direction (X-direction). The length of each of the second interconnection structures 171 and 173 in the first direction (X-direction) may be less than the length of the first interconnection structure 170 in the first direction (X-direction).

A portion of the first interconnection structures 170 and the second interconnection structures 171 and 173 may be connected to the first conductive structures 140a and the 4-1 conductive structures 140a_2 through the third contact plugs 166. A portion of the first interconnection structures 170 may be connected to the second conductive structures 140b and the 4-2 conductive structures 140b_2 through the fourth contact plugs 167.

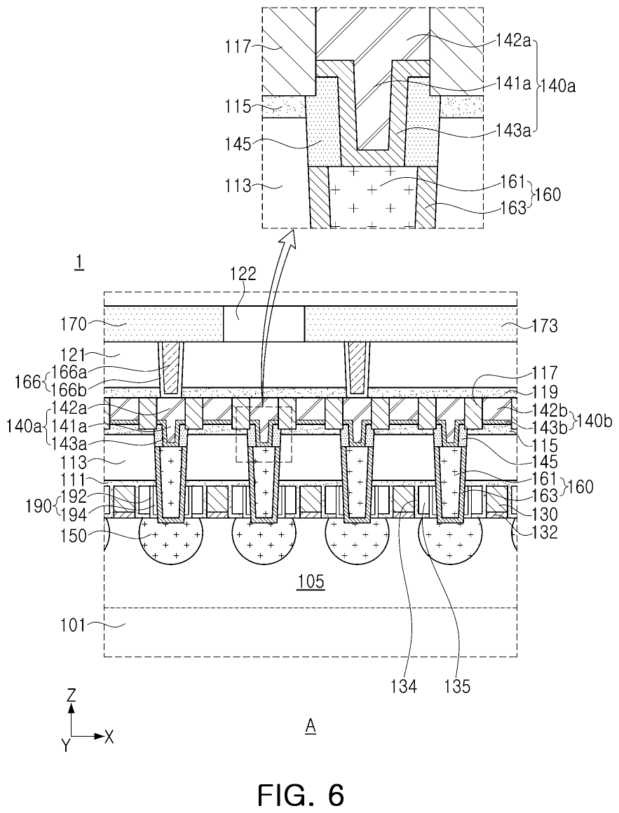

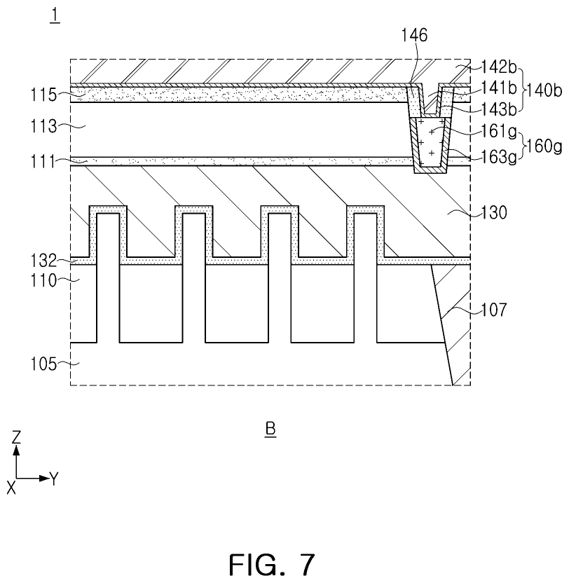

FIG. 3 is a cross-sectional diagram illustrating the semiconductor device illustrated in FIG. 2A taken along line I-I′. FIG. 4 is a cross-sectional diagram illustrating the semiconductor device illustrated in FIG. 2A taken along line II-II′. FIG. 5 is a cross-sectional diagram illustrating a second structure of the semiconductor device illustrated in FIG. 2A taken along line III-III′. FIG. 6 is an enlarged diagram illustrating region “A” of the semiconductor device illustrated in FIG. 3 according to an example embodiment. FIG. 7 is an enlarged diagram illustrating region “B” of the semiconductor device illustrated in FIG. 4.

Referring to FIGS. 3, 4, and 5 along with FIG. 1C, a semiconductor device 1 may include a first structure ST1 and a second structure ST2 in contact with the first structure ST1. In an example, the first structure ST1 may include a cell transistor cTR in a memory cell array region CA, a data storage structure DS, and cell routing interconnections CR electrically connected to the cell transistor cTR and the data storage structure DS.

The cell transistor cTR may include a bitline BL extending in the first direction (X-direction), a wordline WL extending in the second direction (Y-direction), back gate lines BG extending in the second direction (Y-direction), and cell active regions cACT.

The cell active regions cACT may include a semiconductor material which may be used as a channel of the transistor. The cell active regions cACT may include at least one of a silicon layer, an oxide semiconductor layer, and a two-dimensional material layer having semiconductor properties. For example, each of the cell active regions cACT may include single crystal silicon or polysilicon. The cell active regions cACT may be a bar shape extending in the first direction (X-direction) and the second direction (Y-direction). Each of the cell active regions cACT may include a first cell source/drain region cSD1, a second cell source/drain region cSD2 disposed at a level higher than a level of the first cell source/drain region cSD1, and a cell channel region cCH between the first and second cell source/drain regions cSD1 and cSD2. The cell active regions cACT may be referred to as a cell semiconductor layer or a vertical channel layer. Each of the cell transistors cTR may further include a cell gate dielectric layer in contact with a side surface of the cell channel region cCH and a side surface of the wordline WL. A portion of the wordline WL opposing the cell channel region cCH may be a gate electrode. Each of the wordlines WL may have a vertical length in the vertical direction (Z-direction) greater than a width in the first direction (X-direction).

The back gate line BG may oppose a side surface of the cell channel region cCH. A back gate dielectric layer may be disposed between the back gate line BG and the cell channel region cCH. The cell channel region cCH may be disposed between the wordline WL and the back gate line BG. A pair of adjacent cell active regions cACT may be disposed between a pair of adjacent wordlines WL. The back gate line BG may be disposed between the pair of cell active regions cACT. The back gate line BG may be configured as a back gate electrode. The back gate line BG may control charges accumulated in the cell channel region cCH. The cell channel region cCH may be a floating body disposed between the first and second cell source/drain regions cSD1, cSD2, and the back gate line BG may suppress or prevent performance of the cell transistor cTR from being degraded due to a floating body effect, and may improve performance of the cell transistor cTR.

The wordline WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, for example, as the present disclosure is not necessarily limited thereto. Each of the wordlines WL may include a single layer or multiple layers formed of the aforementioned conductive materials. The back gate lines BG may include at least one conductive material. For example, each of the back gate lines BG may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, for example, as the present disclosure is not necessarily limited thereto. Each of the back gate lines BG may include a single layer or multiple layers formed of the materials described above.

The bitlines BL may be electrically connected to the cell active regions cACT on the cell active regions cACT. For example, the bitlines BL may be electrically connected to the first cell source/drain region cSD1 of the cell active regions cACT.

Each of the bitlines BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, for example, as the present disclosure is not necessarily limited thereto. Each of the bitlines BL may include a single layer or multiple layers formed of the aforementioned conductive materials. For example, each of the bitlines BL may include a first conductive layer 250 and a second conductive layer 252 on the first conductive layer 250. The first conductive layer 250 may include doped silicon, and the second conductive layer 252 may include a conductive material having a resistivity lower than that of doped silicon among the aforementioned conductive materials.

The first structure ST1 may further include a shield conductive structure SL including line portions LP alternately arranged with the bitlines BL and a connection portion PP covering upper surfaces of the bitlines BL. The connection portion PP may be in a plate shape. The shield conductive structure SL may be spaced apart from the bitlines BL. The shield conductive structure SL may screen capacitive coupling between the bitlines BL. For example, the shield conductive structure SL may reduce resistive-capacitive delay (RC delay) of the bitlines BL by reducing or blocking parasitic capacitance between the bitlines BL.

The first structure ST1 may further include cell routing interconnections CR, wordline contact structures 271 and 272, and bitline contact structures 273 and 274. The cell routing interconnections CR may include first interconnections 270, second interconnections 237, first conductive vias 275 connecting the first interconnections 270 to each other, and first through-plugs 260 connecting the first interconnections 270 connected to each other below the bitline BL and the second interconnections 237 on the data storage structure DS to each other. The wordline contact structures 271 and 272 may electrically connect the wordline WL to the cell routing interconnections CR. The bitline contact structures 273 and 274 may electrically connect the bitline BL to the cell routing interconnections CR.

The data storage structure DS may be disposed at a level higher than a level of the wordline WL. The data storage structure DS may include first electrodes 261 extending in the vertical direction (Z-direction), a second electrode 263 covering a side surface and a lower surface of the first electrodes 261, and a dielectric layer 262 between the first electrodes 261 and the second electrode 263.

The data storage structure DS may include cell capacitors for storing data in a memory such as DRAM, for example, as the present disclosure is not necessarily limited thereto. For example, the data storage structure DS may be configured as a data storage structure of MRAM or a data storage structure of FeRAM.

The first structure ST1 may further include contact structures 233 electrically connecting the second cell source/drain region cSD2 to the first electrodes 261. Each of the contact structures 233 may include a plug portion 234 in contact with the cell active region cACT and a pad portion 235 below the plug portion 234. The data storage structures DS may be disposed on the pad portion 235.

The first structure ST1 may further include a capacitor interconnection 239 disposed on capacitor vias 236 and a capacitor interconnection 239 disposed on the capacitor vias 236 and extending to an external side of the data storage structure DS.

The first structure ST1 may further include a base substrate 10, a first insulating structure 11 on the base substrate 10, a second insulating structure 22, a third insulating layer 21, a fourth insulating layer 20, a fifth insulating structure 15, and a first bonding adhesive layer 19.

The first insulating structure 11 may be disposed on the base substrate 10. The bitlines BL, the shield conductive structure SL, the wordline contact structure 271 and 272, the bitline contact structure 273 and 274, the first interconnections 270, and the first conductive vias 275 may be disposed in the first insulating structure 11. The cell transistor cTR and the back gate lines BG may be disposed in the second insulating structure 22. The third insulating layer 21 may be disposed on side surfaces of the plug portions 234. The fourth insulating layer 20 may be disposed on side surfaces of the pad portions 235. The data storage structures DS and the second interconnections 237 may be disposed in the fifth insulating structure 15. The first through-plugs 260 may penetrate a portion of the first insulating structure 11, the second insulating structure 22, the third insulating layer 21, the fourth insulating layer 20, and the fifth insulating structure 15. The first bonding adhesive layer 19 may be disposed on the fifth insulating structure 15. The first bonding adhesive layer 19 may be a portion of the fifth insulating structure 15, and an upper surface of the first bonding adhesive layer 19 may be bonded to the second bonding adhesive layer 109 of the second structure ST2. Accordingly, an upper surface of the first structure ST1 and a lower surface of the second structure ST2 may be bonded to each other and a bonding surface may be formed.

Referring to FIGS. 3, 4, 5, 6 and 7, the second structure ST2 may include a second bonding adhesive layer 109, a substrate 101 including an active region 105 on the second bonding adhesive layer 109, gate structures GS including a gate electrode 130 alternately extending with the active region 105, source/drain regions 150, a first contact plug 160 connected to the source/drain region 150, a second contact plug 160g connected to the gate electrode 130, a first conductive structure 140a disposed on the first contact plug 160, a second conductive structure 140b disposed on the second contact plug 160g, a third contact plug 166 disposed on the first conductive structure 140a, a fourth contact plug (e.g., fourth contact plug 167) on the second conductive structure 140b, first interconnection structures 170 disposed on the third and fourth contact plugs 166 and 167, and second interconnection structures 171 and 173.

The substrate 101 may include an active region 105 disposed on an upper side. The active regions 105 may have a fin structure. The active region 105 may partially protrude on the device isolation layer 110, such that an upper surface of the active region 105 may be positioned at a level higher than a level of the upper surface of the device isolation layer 110. The active region 105 may be formed as a portion of the substrate 101, or may include an epitaxial layer grown from the substrate 101. The active region 105 may be partially recessed on both sides of the gate structure GS and recess regions may be formed, and source/drain regions 150 may be disposed in the recess regions.

The active region 105 may or may not include a well region including impurities. For example, as for a P-type transistor pFET, the well region may include N-type impurities such as phosphorus (P), arsenic (As), or antimony (Sb), and as for an N-type transistor nFET, the well region may include P-type impurities such as boron (B), gallium (Ga), or indium (In). The well region may be positioned at a predetermined depth from, for example, an upper surface of the active region 105.

A device isolation layer 110 may define the active region 105 in the substrate 101. The device isolation layer 110 may be formed by, for example, a shallow trench isolation (STI) process. The device isolation layer 110 may expose an upper surface of the active region 105, and may also expose a portion of an upper portion of the active region 105. The device isolation layer 110 may be formed of an insulating material. The device isolation layer 110 may be, for example, an oxide, a nitride, or a combination thereof.

The second structure ST2 may include a device isolation pattern 107 for partitioning active regions 105 in the first region R1 and active regions 105 in the second region R2 between the first region R1 and the second region R2. The device isolation pattern 107 may have a trench shape buried from the upper surface to the lower surface of the substrate 101. The device isolation pattern 107 may extend in the first direction (X-direction) and a width thereof may reduce downwardly.

Each of the gate structures GS may include a gate electrode 130, a gate dielectric layer 132 between the gate electrode 130 and the active region 105, a gate capping liner 134 surrounding a side surface of the gate dielectric layer 132, an upper surface of the gate electrode 130 and a side surface of the gate electrode 130, and a gate spacer 135 on the side surface of the gate electrode 130. The gate capping liner 134 of the gate structure GS may not be provided.

The gate electrodes 130 may be spaced apart from each other in the first direction (X-direction) and may extend in the second direction (Y-direction).

The gate electrode 130 may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In example embodiments, the gate electrode 130 may include two or more multilayers.

A gate structure GS may overlap four active regions 105 having fin structures in the vertical direction (Z-direction). However, an example embodiment thereof is not limited thereto, and for example, a gate structure GS may overlap two or three active regions 105 having fin structures in the vertical direction (Z-direction).

The gate dielectric layers 132 may be disposed between the active region 105 and the gate electrode 130. The gate dielectric layers 132 may include oxide, nitride, or a high-κ material. The high-κ material may refer to a dielectric material having a dielectric constant higher than that of a silicon oxide (SiO₂). The high-κ material may refer to a dielectric material having a higher dielectric constant than a silicon oxide (SiO₂) film. The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In example embodiments, the gate dielectric layer 132 may be formed of a multilayer film.

The gate capping liner 134 may cover an upper surface of the gate electrode 130 and may extend to a region between a side surface of the gate electrode 130 and the gate spacer 135, and between a side surface of the gate dielectric layer 132 and the gate spacer 135 to an upper surface of the active region 105. The gate spacer 135 may surround a side surface of the gate electrode 130 and a side surface of the gate dielectric layer 132. The gate capping liner 134 and the gate spacer 135 may be formed of at least one of oxide, nitride, and oxynitride, for example, a low-k film.

The source/drain regions 150 may be disposed in recess regions formed by recessing a portion of the active region 105 on both sides of the gate structure GS. The source/drain regions 150 may include a semiconductor material, for example, at least one of silicon (Si) and germanium (Ge), and may further include dopants. For example, when the semiconductor device 1 is configured as a pFET, the dopants may be at least one of boron (B), gallium (Ga), and indium (In). The source/drain regions 150 may be formed of an epitaxial layer.

The second structure ST2 may further include insulating structures 190 disposed between the gate structures GS. The insulating structure 190 may include an insulating liner 192 and a spacer 194. The insulating liner 192 may extend from a side surface of the gate structures GS to the source/drain regions 150, and the spacer 194 may be disposed on the insulating liner 192. Each of the insulating liner 192 and the spacer 194 may include at least one of oxide, nitride, and oxynitride. The insulating liner 192 may include a material different from that of the spacer 194, for example, as the present disclosure is not necessarily limited thereto. For example, the insulating liner 192 may include silicon nitride, and the spacer layer 164 may include silicon oxide.

The second structure ST2 may further include a first insulating liner 111 on the gate structures GS and the insulating structures 190, a first insulating layer 113 on the first insulating liner 111, and a second insulating liner 115 on the first insulating layer 113. In an example, the first insulating liner 111 and the second insulating liner 115 may include a first insulating material, and the first insulating layer 113 may include a second insulating material different from the first insulating material. For example, the first insulating material may be formed of at least one of nitride, and oxynitride. The second insulating material may include silicon oxide. In an example, the first insulating liner 111 and the second insulating liner 115 may include different insulating materials.

The first contact plugs 160 may penetrate the insulating structure 190 and the first insulating liner 111, may be connected to the source/drain region 150 and may apply an electrical signal to the source/drain regions 150. In an example, the first contact plugs 160 may be recessed into the source/drain region 150 and may extend into the source/drain region 150. In an example, each of the first contact plugs 160 may include a first conductive pattern 161 and a first conductive barrier layer 163 surrounding a side surface and a lower surface of the first conductive pattern 161.

The second contact plugs 160g may penetrate the insulating structure 190 and the first insulating liner 111, may be connected to the gate electrode 130, and may apply an electrical signal to the gate electrode 130. In an example, the second contact plug 160g may penetrate the first insulating liner 111, may be recessed into the gate electrode 130, and may extend into the gate electrode 130. In an example, each of the second contact plugs 160g may include a second conductive pattern 161g, and a second conductive barrier layer 161gsurrounding a side surface and a lower surface of the second conductive pattern 161g. In an example, each of the first conductive pattern 161 and the second conductive pattern 161gmay include a metal material such as tungsten, aluminum, or copper. The first conductive barrier layer 163 and the second conductive barrier layer 161gmay include metal nitride such as titanium nitride, tantalum nitride, and tungsten nitride.

The upper surface of the first contact plug 160 and the upper surface of the second contact plug 160g may be disposed at the same level. The lower surface of the first contact plug 160 may be disposed at a level lower than a level of the lower surface of the second contact plug 160g. The term “level” as used herein may refer to a distance of an element or layer (or surface thereof) from or relative to a reference element or layer (or surface thereof), for example, the substrate 101. Elements at a same level may have substantially coplanar surfaces.

The upper surface of the first contact plug 160 and the upper surface of the second contact plug 160g may be disposed between the lower surface and the upper surface of the first insulating layer 113. The side surface of the first contact plug 160 may be surrounded by the insulating structure 190, the first insulating liner 111, and the first insulating layer 113. The side surface of the second contact plug 160g may be surrounded by the first insulating liner 111 and the first insulating layer 113.

Each of the first conductive structures 140a may be connected to the first contact plug 160 on the first contact plug 160 and may extend in the second direction (Y-direction). Each of the first conductive structures 140a may include a first via portion 141a disposed on the first contact plug 160, a first interconnection portion 142a extending from the first via portion 141a on the second insulating liner 115 in the second direction (Y-direction), and a first contact barrier layer 143a covering the side surface and the lower surface of the first via portion 141a and disposed on the lower surface of the first interconnection portion 142a.

The first via portion 141a of the first conductive structure 140a may penetrate the first insulating layer 113 and the second insulating liner 115 on the first contact plug 160 and may have a lower surface in contact with an upper surface of the first contact plug 160.

A horizontal width of the first via portion 141a of the first conductive structure 140a in the first direction (X-direction) may be smaller than a horizontal width of the first via portion 141a in the second direction (Y-direction).

The first interconnection portion 142a of the first conductive structure 140a may extend from the first via portion 141a on the first via portion 141a. The first interconnection portion 142a of the first conductive structure 140a may extend in the second direction (Y-direction) on the second insulating liner 115. A width in the first direction (X-direction) of the first via portion 141a may be smaller than a width in the first direction (X-direction) of the first interconnection portion 142a.

Each of the second conductive structures 140b may be connected to the second contact plug 160g on the second contact plug 160g and may extend in the second direction (Y-direction). Each of the second conductive structures 140b may include a second via portion 141b disposed on the second contact plug 160g, a second interconnection portion 142b extending from the second via portion 141b on the second insulating liner 115 and extending in the second direction (Y-direction), and a second contact barrier layer 143b covering a side surface and a lower surface of the second via portion 141b and disposed on a lower surface of the second interconnection portion 142b. In an example, a lower surface of the second via portion 141b of the second conductive structure 140b may be disposed at the same level as a lower surface of the first via portion 141a of the first conductive structure 140a. The upper surface of the second interconnection portion 142b of the second conductive structure 140b may be coplanar with the upper surface of the first interconnection portion 142a of the first conductive structure 140a.

The first via portion 141a and the first interconnection portion 142a of the first conductive structure 140a and the second via portion 141b and the second interconnection portion 142b of the second conductive structure 140b may include metal nitride such as titanium nitride, tantalum nitride, or tungsten nitride. The first contact barrier layer 143a of the first conductive structure 140a and the second contact barrier layer 143b of the second conductive structure 140b may include metal nitride such as titanium nitride, tantalum nitride, or tungsten nitride.

The second via portion 141b of the second conductive structure 140b may penetrate the first insulating layer 113 and the second insulating liner 115 on the second contact plug 160g and may have a lower surface in contact with an upper surface of the second contact plug 160g.

The second interconnection portion 142b of the second conductive structure 140b may extend from the second via portion 141b on the second via portion 141b. The second interconnection portion 142b of the second conductive structure 140b may be disposed on the second insulating liner 115 and may extend in the second direction (Y-direction). A width of the second via portion 141b in the first direction (X-direction) may be smaller than a width of the second interconnection portion 142b in the first direction (X-direction).

The first conductive structures 140a and the second conductive structures 140b may be disposed alternately in the first direction (X-direction).

The second structure ST2 may further include first insulating patterns 117 disposed between the first interconnection portions 142a of the first conductive structures 140a and the second interconnection portions 142b of the second conductive structures 140b. The first insulating patterns 117 may be disposed on a side surface of the first interconnection portion 142a and side surfaces of the second interconnection portion 142b. An upper surface of the first insulating pattern 117 may be coplanar with upper surfaces of the first and second conductive structures 140a and 140b.

The upper surface of the first conductive structure 140a may be disposed at the same level as the upper surface of the second conductive structure 140b. The lower surface of the first conductive structure 140a may be disposed at a level lower than a level of the lower surface of the second conductive structure 140b.

The second structure ST2 may further include a first contact spacer 145 disposed on a side surface of a first via portion 141a of the first conductive structure 140a and a second contact spacer 146 disposed on a side surface of a second via portion 141b of the second conductive structure 140b.

The first contact spacer 145 may penetrate the second insulating liner 115 and may be disposed on a side surface of the first via portion 141a between the first contact plug 160a and the first interconnection portion 142a of the first conductive structure 140a. The second contact spacer 146 may penetrate the second insulating liner 115 and may be disposed on a side surface of the second via portion 141b between the second contact plug 160g and the second interconnection portion 142b of the second conductive structure 140b.

The first contact spacer 145 may overlap the first contact plug 160a in the vertical direction (Z-direction). The second contact spacer 146 may overlap the second contact plug 160g in the vertical direction (Z-direction).

A side surface of the first contact spacer 145 may be in contact with the first insulating layer 113, the second insulating liner 115, and the first insulating patterns 117.

A side surface of the first contact spacer 145 may be disposed on a line extending upwardly from a side surface of the first contact plug 160. The side surface of the first contact spacer 145 may be in contact with the first insulating layer 113 and the second insulating liner 115, and the side surface of an upper region of the first contact spacer 145 may be exposed from the second insulating liner 115. The side surface of the upper region of the first contact spacer 145 exposed from the second insulating liner 115 may be in contact with the first insulating patterns 117. In an example, the side surface of the second contact spacer 146 may be disposed on a line extending upwardly from the side surface of the second contact plug 160g. The side surface of the second contact spacer 146 may be in contact with the first insulating layer 113 and the second insulating liner 115, and the side surface of the upper region of the second contact spacer 146 may be exposed from the second insulating liner 115.

The second insulating liner 115 may include a first portion overlapping the first insulating patterns 117 and a second portion overlapping the first and second conductive structures 140a and 140b. The second portion of the second insulating liner 115 may overlap the first interconnection portion 142a of the first conductive structure 140a and the second interconnection portion 142b of the second conductive structure 140b. In an example, a thickness of the first portion of the second insulating liner 115 may be less than a thickness of the second portion of the second insulating liner 115. The upper surface of the first portion of the second insulating liner 115 may be disposed at a level lower than a level of the upper surface of the second portion of the second insulating liner 115.

A width in the first direction (X-direction) of a lower surface of the first via portion 141a of the first conductive structure 140a may be smaller than a width in the first direction (X-direction) of an upper surface of the first contact plug 160. The width in the first direction (X-direction) of the lower surface of the second via portion 141b of the second conductive structure 140b may be smaller than the width in the first direction (X-direction) of the upper surface of the second contact plug 160g.

The upper surface of the first contact plug 160 and the lower surface of the first via portion 141a of the first conductive structure 140a may be disposed between the lower surface and the upper surface of the first insulating layer 113. In an example, the upper surface of the first contact plug 160 and the lower surface of the first via portion 141a of the first conductive structure 140a may be disposed adjacent to the lower surface of the first insulating layer 113 between the lower surface and the upper surface of the first insulating layer 113. However, an example embodiment thereof is not limited thereto, and the upper surface of the first contact plug 160 and the lower surface of the first via portion 141a of the first conductive structure 140a may be disposed adjacent to the upper surface of the first insulating layer 113. Positions of the upper surface of the first contact plug 160 and the lower surface of the first via portion 141a of the first conductive structure 140a may be varied between the lower surface and the upper surface of the first insulating layer 113.

According to example embodiments, a semiconductor device 1 may include a first contact plug 160 connected to the source/drain region 150, a second contact plug 160g connected to the gate structure GS, a first conductive structure 140a connected to the first contact plug 160, and a second conductive structure 140b connected to the second contact plug 160g and disposed alternately with the first conductive structure 140a in the first direction (X-direction). The semiconductor device 1 may further include a first contact spacer 145 disposed on a side surface of a first via portion 141a of the first conductive structure 140a and a second contact spacer 146 disposed on a side surface of a second via portion 141b of the second conductive structure 140b, thereby ensuring a spacing distance between the first interconnection portion 142a of the first conductive structure 140a and the second interconnection portion 142b of the second conductive structure 140b adjacent to the first conductive structure 140a, as well as ensuring a spacing distance between the first via portion 141a of the first conductive structure 140a and the second interconnection portion 142b of the second conductive structure 140b. Accordingly, the use of the first contact spacer 145 and the second contact spacer 146 to ensure spacing distances between structures may be advantageous in preventing or significantly reducing the likelihood of a bridge phenomenon, particularly with respect to a bridge phenomenon occurring between the first conductive structure 140a and the second conductive structure 140b. The present disclosure may thus prevent or otherwise limit the potentiality of a bridge phenomenon influencing operations, which may provide a semiconductor device having improved reliability and electrical properties.

The second structure ST2 may further include a third insulating liner 119 disposed on the first and second conductive structures 140a and 140b and the first insulating patterns 117 and a second insulating layer 121 disposed on the third insulating liner 119. The third insulating liner 119 may include a first insulating material and the second insulating layer 121 may include a second insulating material different from the first insulating material. For example, the third insulating liner 119 may include silicon nitride and/or oxynitride and the second insulating layer 121 may include silicon oxide.

The third contact plug 166 may penetrate the third insulating liner 119 and the second insulating layer 121, may be disposed on the first conductive structure 140a and may be connected to the first conductive structure 140a. The fourth contact plug 167 may penetrate the third insulating liner 119 and the second insulating layer 121, may be disposed on the second conductive structure 140b and may be connected to the second conductive structure 140b.

In an example, the third contact plug 166 may include a third conductive pattern 166a and a third conductive barrier layer 166b covering a side surface and a lower surface of the third conductive pattern 166a. The fourth contact plug 167 may have the same structure as that of the third contact plug 166.

The first interconnection structures 170 and the second interconnection structures 171 and 173 may be disposed on the third and fourth contact plugs 166 and 167. Each of the first interconnection structures 170 and the second interconnection structures 171 and 173 may extend in the first direction (X-direction). At least one interconnection structure among the first interconnection structures 170 may be connected to the first conductive structure 140a through a third contact plug 166, and at least another interconnection structure among the first interconnection structures 170 may be connected to the second conductive structure 140b through a fourth contact plug 167.

The second structure ST2 may further include second insulating patterns 122, first to fifth interlayer insulating layers 123-127, first and second vertical vias 174 and 178, first and second horizontal interconnections 172 and 176, an upper interconnection 180, and a second through-plug 60.

The second insulating patterns 122 may be disposed between the first interconnection structures 170 and the second interconnection structures 171 and 173. The first to fifth interlayer insulating layers 123-127 may be stacked in order in the vertical direction (Z-direction) on the first interconnection structures 170 and the second interconnection structures 171 and 173.

The first horizontal interconnection 172 may penetrate the second insulating patterns 122. The second through-plug 60 may be connected to the first horizontal interconnection 172, may penetrate the second insulating layer 121, the first, second, and third insulating liners 111, 115, and 119, the first insulating pattern 117, the first insulating layer 113, the insulating structure 190, the substrate 101, and the second bonding adhesive layer 109, and the second through-plug 60 may penetrate the first bonding adhesive layer 19 and the fifth insulating structure 15 of the first structure ST1, and may be connected to at least one of the second interconnections 237 of the first structure ST1. The first structure ST1 and the second structure ST2 may be electrically connected through the first and second through-plugs 260 and 60, and the second interconnections 237.

The second through-plug 60 may include a conductive pillar 62 and a conductive barrier layer 64 covering a side surface and a lower surface of the conductive pillar 62.

The first vertical vias 174 may be disposed on first interconnection structures 170 and second interconnection structures 171 and 173 and may be connected to the first interconnection structures 170 and the second interconnection structures 171 and 173. The first vertical vias 174 may penetrate the first interlayer insulating layer 123. Second horizontal interconnections 176 may be disposed on the first vertical vias 174, the second interlayer insulating layer 124 may cover a side surface of the second horizontal interconnections 176, and the second vertical via 178 may penetrate second third, fourth, and fifth interlayer insulating layers 124, 125, 126, and 127 and may be connected to the second horizontal interconnection 176. An upper interconnection 180 may be disposed on the fifth interlayer insulating layer 127. The upper interconnection 180 may be connected to the second horizontal interconnection 176 through the second vertical via 178.

Each of the first and second vertical vias 174 and 175, the first and second horizontal interconnections 172 and 176 and the upper interconnection 180 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, for example, as the present disclosure is not necessarily limited thereto. However, an example embodiment may include a single layer or multiple layers formed of the aforementioned materials.

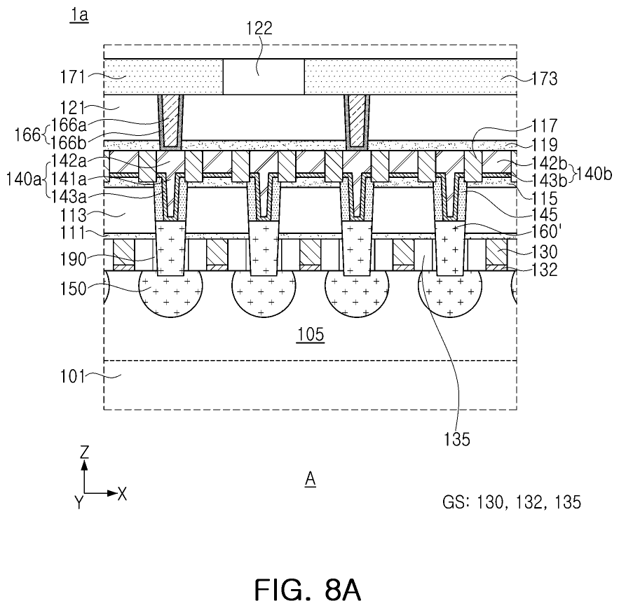

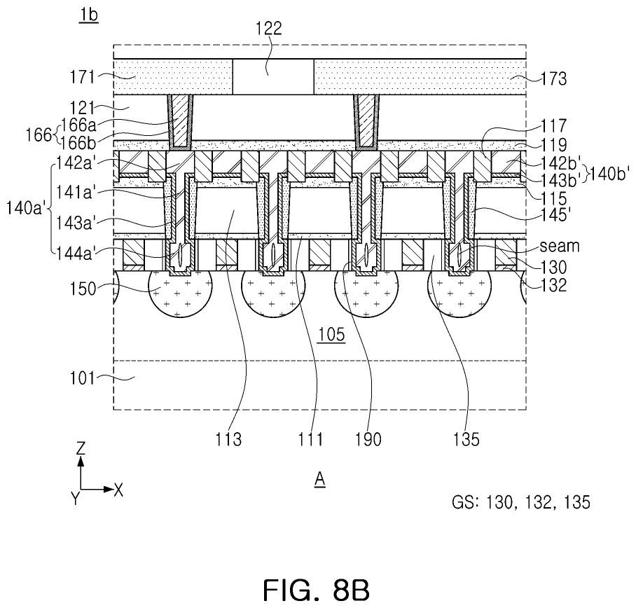

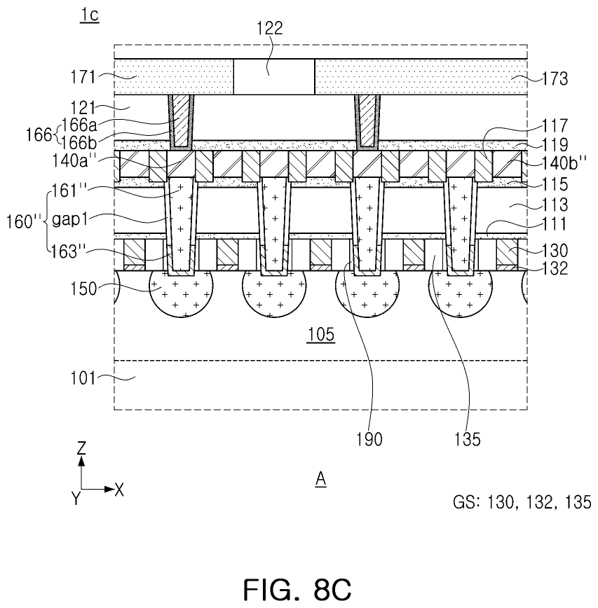

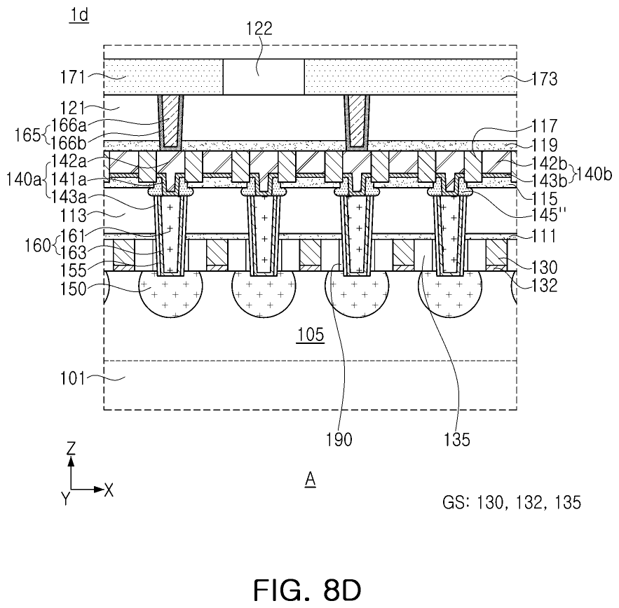

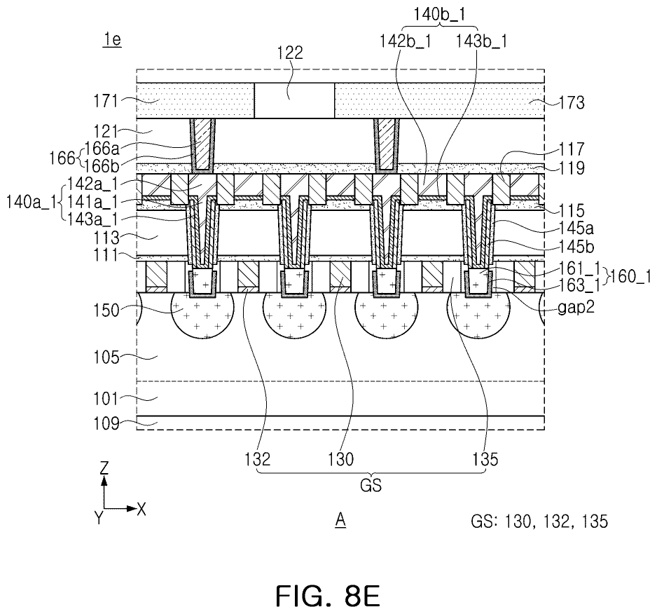

FIGS. 8A to 8E are enlarged diagrams illustrating region “A” of the semiconductor device illustrated in FIG. 3 according to other example embodiments.

Referring to FIG. 8A, the description overlapping the same or corresponding elements in FIG. 6 among the other elements of the semiconductor device 1a other than a first contact plug 160′ may not be provided. The semiconductor device 1a in FIG. 8A may include a gate structure GS in which the gate capping liner 134 of the semiconductor device 1 in FIG. 6 is not provided.

The gate structure GS may include a gate electrode 130, a gate dielectric layer 132 disposed between the gate electrode 130 and the active region 105, and a gate spacer 135 disposed on a side surface of the gate electrode 130 and a side surface of the gate dielectric layer 132. The gate spacer 135 may be in contact with the side surface of the gate electrode 130, the side surface of the gate dielectric layer 132, the upper surface of the active region 105, and the upper surface of the source/drain region 150.

The insulating structures 190 may be disposed between the gate structures GS.

The first contact plug 160′ may penetrate the first insulating liner 111 and the spacer 194 and may be connected to the source/drain region 150. The first contact plug 160′ may be recessed into the source/drain region 150 and may extend into the source/drain region 150. In an example, the first contact plug 160′ may have a single conductive pattern structure without a conductive barrier layer. The first contact plug 160′ may include a metal material such as aluminum or copper, other than tungsten.

Referring to FIG. 8B, as for the semiconductor device 1b, overlapping descriptions of elements the same or corresponding to the elements in FIG. 6 among the other elements other than a first conductive structure 140a′ and first contact spacers 145′ may not be provided.

A second structure ST2 of the semiconductor device 1b may include a substrate 101 including an active region 105, gate structures GS including a gate electrode 130 alternately extending to the active region 105, source/drain regions 150, a first conductive structure 140a′ connected to the source/drain region 150, a second conductive structure 140b′ connected to the gate electrode 130, a third contact plug 166 disposed on the first conductive structure 140a′, a fourth contact plug (e.g., fourth contact plug 167) on the second conductive structure 140b′, and second interconnection structures 171 and 173 on the third contact plug 166.

The first conductive structure 140a′ may include a first lower region 144a′ in contact with the source/drain region 150, a first intermediate region 141a′ extending from the first lower region 144a′ on the first lower region 144a′, a first upper region 142a′ extending from the first intermediate region 141a′ on the first intermediate region 141a′, and a first contact barrier layer 143a′ covering a side surface and a lower surface of the first lower region 144a′, the side surface of the first intermediate region 141a′ and the lower surface of the first upper region 142a′.

The first lower region 144a′ may be disposed below the first insulating liner 111 and may have a side surface in contact with the insulating structure 190. The first intermediate region 141a′ may penetrate the first insulating liner 111, the first insulating layer 113, and the second insulating liner 115, and may extend from the first lower region 144a′. The first upper region 142a′ may extend from the first intermediate region 141a′, may be disposed on the second insulating liner 115, and may extend in the second direction (Y-direction).

The lower surface of the first lower region 144a′ may be recessed into the source/drain region 150 and may extend into the source/drain region 150. The first lower region 144a′ may be a region extending in the first direction (X-direction) further than the first intermediate region 141a′. A width in the first direction (X-direction) of the first lower region 144a′ on the substrate 101 may be greater than a width in the first direction (X-direction) of the first intermediate region 141a′. For example, the first lower region 144a′ may include a portion having a width greater in the first direction (X-direction) than a width of the first intermediate region 141a′. For example, a lower surface of the first intermediate region 141a′ may be connected to an upper surface of the first lower region 144a′, and the width in the first direction (X-direction) of the lower surface of the first intermediate region 141a′ may be smaller than the width in the first direction (X-direction) of the upper surface of the first lower region 144a′. The width of the first upper region 142a′ in the first direction (X-direction) may be greater than the width of the first intermediate region 141a′ in the first direction (X-direction).

In an example, the first conductive structure 140a′ may include a seam extending in the vertical direction (Z-direction) in the first lower region 144a′.

The second conductive structure 140b′ may include a second lower region (not illustrated) in contact with the gate electrode 130, a second intermediate region (not illustrated) extending from the second lower region on the second lower region, a second upper region 142b′ extending from the second intermediate region on the second intermediate region, and a second contact barrier layer 143b′ covering a side surface and a lower surface of the second lower region, a side surface of the second intermediate region, and a lower surface of the second upper region. A width in the first direction (X-direction) of the second lower region may be greater than a width in the first direction (X-direction) of the second intermediate region. A width in the first direction (X-direction) of the second upper region 142b′ may be greater than a width in the first direction (X-direction) of the second intermediate region.

The first conductive structure 140a′ and the second conductive structure 140b′ may be disposed alternately in the first direction (X-direction).

The second structure ST2 of the semiconductor device 1b may further include a first contact spacer 145′ disposed between the first lower region 144a′ and the first upper region 142a′ of the first conductive structure 140a′ and disposed on a side surface of the first intermediate region 141a′. The first contact spacer 145′ may penetrate the first insulating liner 111, the first insulating layer 113, and the second insulating liner 115. For example, the first contact spacer 145′ may include a portion overlapping the first lower region 144a′ and the first upper region 142a′ in the vertical direction (Z-direction).

The first insulating patterns 117 may be disposed between the first upper region 142a′ of the first conductive structure 140a′ and the second upper region 142b′ of the second conductive structure 140b′.

Referring to FIG. 8C, as for the semiconductor device 1c, overlapping descriptions of elements the same as or corresponding to the elements disposed in FIG. 6 among the elements other than a first contact plug 160″ and first and second conductive structures 140a″ and 140b″ connected to the source/drain region 150 may not be provided.

A second structure ST2 of a semiconductor device 1c may include a substrate 101 including an active region 105, gate structures GS including a gate electrode 130 alternately extending with the active region 105, source/drain regions 150, a first contact plug 160″ connected to the source/drain region 150, a second contact plug (not illustrated) connected to the gate electrode 130, a first conductive structure 140a″ on the first contact plug 160″, a second conductive structure 140b″ on the second contact plug (not illustrated), a third contact plug 166 disposed on the first conductive structure 140a″, a fourth contact plug (e.g., the fourth contact plug 167) on the second conductive structure 140b′, and second interconnection structures 171 and 173 on the third contact plug 166.

The first contact plugs 160″ may be disposed between the gate electrodes 130 and may be connected to the source/drain regions 150. The first contact plug 160″ may penetrate the insulating structure 190, the first insulating liner 111, the first insulating layer 113, and the second insulating liner 115, may be connected to the source/drain region 150 and may apply an electrical signal to the source/drain region 150.

The first contact plug 160″ may include the first conductive pattern 161″, the first conductive barrier layer 163″ disposed on a lower surface of the first conductive pattern 161″ and a lower region of the side surface of the first conductive pattern 161″, and a first gap region gap1 disposed on the side surface of an upper region of the first conductive pattern 161″.

The first conductive barrier layer 163″ may cover the side surface of the first conductive pattern 161″ disposed below the first insulating liner 111 and the lower surface of the first conductive pattern 161″.

The first gap region gap1 may be an air gap extending to the first conductive barrier layer 163″. The first gap region gap1 may be a region corresponding to a region on the side surface of the first conductive pattern 161″ exposed from the first conductive barrier layer 163″. The first gap region gap1 may be disposed between the first conductive pattern 161″ and the insulating structure 190, between the first conductive pattern 161″ and the first insulating liner 111, between the first conductive pattern 161″ and the first insulating layer 113, and between the first conductive pattern 161″ and the second insulating liner 115 on the first conductive barrier layer 163″.

In another example embodiment, the first conductive barrier layer 163″ may cover a lower surface of the first conductive pattern 161″, and may extend to the side surface of the first conductive pattern 161″ disposed on the first insulating liner 111. In this case, the lower surface of the first gap region gap1 may be disposed on the first conductive barrier layer 163″ extending to the first insulating liner 111.

The first conductive structures 140a″ may be electrically connected to the first contact plug 160″ on the second insulating liner 115. The lower surface of the first conductive structure 140a″ may be in contact with the upper surface of the first conductive pattern 161″ of the first contact plug 160″.

The first conductive structure 140a″ and the second conductive structure 140b″ may be disposed alternately in the first direction (X-direction). The second conductive structure 140b″ may be disposed on the second insulating liner 115 and may be disposed on the second contact plug (not illustrated) connected to the gate electrode 130.

The second contact plug (not illustrated) connected to the gate electrode 130 may penetrate the first insulating liner 111, the first insulating layer 113, and the second insulating liner 115, and may have a lower surface in contact with the gate electrode 130. The second contact plug (not illustrated) may include a second conductive pattern (not illustrated), a second conductive barrier layer (not illustrated) surrounding the lower surface of the second conductive pattern and the lower region of the side surface of the second conductive pattern, and a second gap region (not illustrated) on the second conductive barrier layer. The second gap region may correspond to a region on one side surface of the second conductive pattern exposed from the second conductive barrier layer.

The upper surface of the first conductive structure 140a″ and the upper surface of the second conductive structure 140b″ may be coplanar with each other. The first insulating patterns 117 may be disposed between the first conductive structure 140a″ and the second conductive structure 140b″.

According to example embodiments, the semiconductor device 1c may include the first contact plug 160″ including the first gap region gap1, such that capacitance between the gate electrode 130 and the first contact plug 160″ may be reduced, and a semiconductor device having improved electrical properties may be provided.

Referring to FIG. 8D, as for a semiconductor device 1d, overlapping descriptions of the elements the same as or corresponding to the elements disposed in FIG. 6 among the elements other than an auxiliary contact spacer 155 on a side surface of a first contact plug 160 and a first contact spacer 145″ disposed on a first via portion 141a of a first conductive structure 140a may not be provided.

The auxiliary contact spacer 155 may be disposed on the side surface of the first contact plug 160. The auxiliary contact spacer 155 may include at least one of oxide, nitride, and oxynitride.

The first contact spacer 145″ may be disposed on the side surface of the first via portion 141a between the auxiliary contact spacer 155 and the first interconnection portion 142a. A width of the lower surface of the first contact spacer 145″ in the first direction (X-direction) may be greater than a width of the upper surface of the first contact plug 160 in the first direction (X-direction). The first contact spacer 145″ may include a portion protruding toward the first insulating layer 113 on the first contact plug 160 and the auxiliary contact spacer 155.

Referring to FIG. 8E, in the semiconductor device 1e, overlapping descriptions of the elements the same as or corresponding to the elements disposed in FIG. 6 among the elements other than a first contact plug 160_1 and a first conductive structure 140a_1 connected to the first contact plug 160_1 on the first contact plug 160_1 may not be provided.

The first contact plugs 160_1 may be disposed below the first insulating liner 111, may be disposed between the gate electrodes 130 and may be connected to the source/drain regions 150. Each of the first contact plugs 160_1 may include a first conductive pattern 161_1, a first conductive barrier layer 163_1 covering a portion of a lower surface and a side surface of the first conductive pattern 161_1, and a second gap region gap2 disposed on the side surface of the first conductive barrier layer 163_1 and the side surface of the exposed 1-1 and 1-2 contact spacers 145a and 145b on a lower surface of the first insulating liner 111.

The second gap region gap2 may be an air gap corresponding to a region between the side surface of the gate spacer 135 and the side surface of the first conductive barrier layer 163_1 and a region between the side surface of the 1-1 and 1-2 contact spacers 145a and 145b protruding below the first insulating liner 111 and the side surface of the gate spacer 135.

The first conductive structure 140a_1 may penetrate the first insulating liner 111 and may be partially recessed into the upper surface of the first contact plug 160_1, and may be connected to the first contact plug 160_1.

The first conductive structure 140a_1 may include a first via portion 141a_1, a first interconnection portion 142a_1 extending from the first via portion 141a_1 on the first via portion 141a_1, and a first contact barrier layer 143a_1 covering a lower surface and a side surface of the first via portion 141a1_1 and a lower surface of the first interconnection portion 142a_1. In an example, the first conductive structure 140a_1 may be spaced apart from the first conductive barrier layer 163_1 of the first contact plug 160_1 in the vertical direction (Z-direction).

A lower surface of the first conductive structure 140a_1 may be disposed at a level lower than a level of the first insulating liner 111. The first via portion 141a_1 may penetrate the first insulating liner 111, the first insulating layer 113, and the second insulating liner 115. The first via portion 141a_1 may be in contact with the upper surface of the first contact plug 160_1 disposed at a level lower than a level of the first insulating liner 111.

The first via portion 141a_1 may have a lower surface in contact with an upper surface of the first conductive pattern 161_1 of the first contact plug 160_1. The first interconnection portion 142a_1 may extend from the first via portion 141a_1 to the second insulating liner 115 in the second direction (Y-direction). A width of the first via portion 141a_1 in the first direction (X-direction) may be smaller than a width of the first interconnection portion 142a_1 in the first direction (X-direction).

The 1-1 contact spacer 145a and the 1-2 contact spacer 145b may be disposed on a side surface of the first via portion 141a_1. The 1-2 contact spacer 145b may surround the first via portion 141a_1 on the side surface of the first via portion 141a_1 between the first conductive pattern 161_1 and the first interconnection portion 142a_1. The 1-1 contact spacer 145a may surround the 1-2 contact spacer 145b and may be spaced apart from the upper surface of the first conductive pattern 161_1. The 1-2 contact spacer 145b may protrude further downwardly than the 1-1 contact spacer 145a on the lower surface of the first insulating liner 111. The 1-1 contact spacer 145a may not be in contact with the upper surface of the first conductive pattern 161_1. In an example, the 1-1 contact spacer 145a may be disposed between the second gap region gap2 of the first contact plug 160_1 and the first interconnection portion 142a_1. In an example, the 1-1 contact spacer 145a may not overlap the first conductive pattern 161_1 of the first contact plug 160_1 in the vertical direction (Z-direction).

The second conductive structure 140b_1 may include a second via portion (not illustrated) in contact with the gate electrode 130b_1, a second interconnection portion 142b_1 extending from the second via portion to the second insulating liner 115, and a second contact barrier layer 143b_1 covering a lower surface and a side surface of the second via portion and a lower surface of the second interconnection portion 142b_1.

The first conductive structure 140a_1 and the second conductive structure 140b_1 may be disposed alternately in the first direction (X-direction), and the first insulating patterns 117 may be disposed between the first interconnection portion 142a_1 of the first conductive structure 140a_1 and the second interconnection portion 142b_1 of the second conductive structure 140b_1.

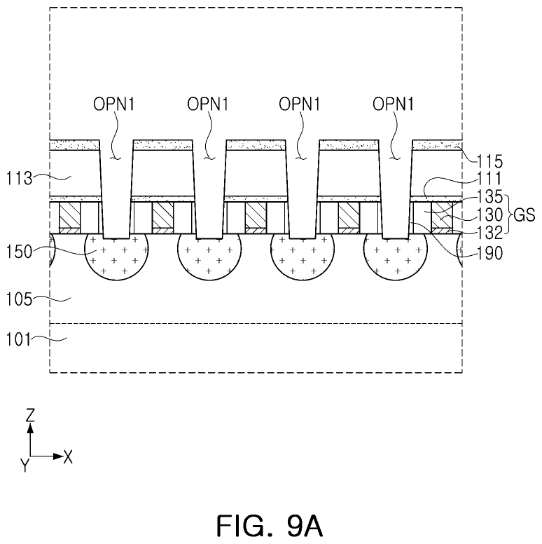

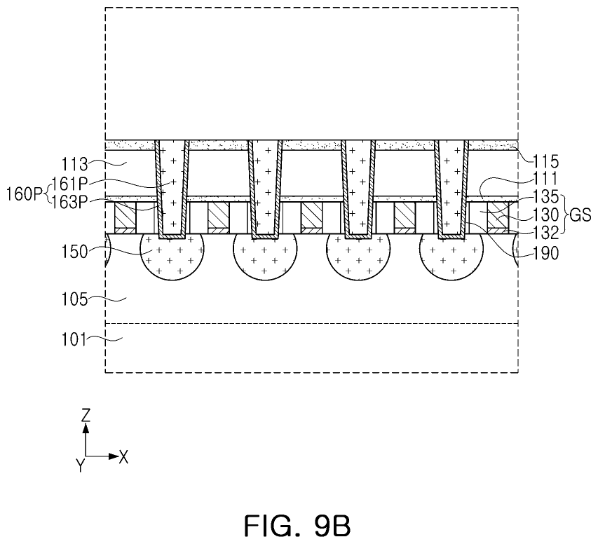

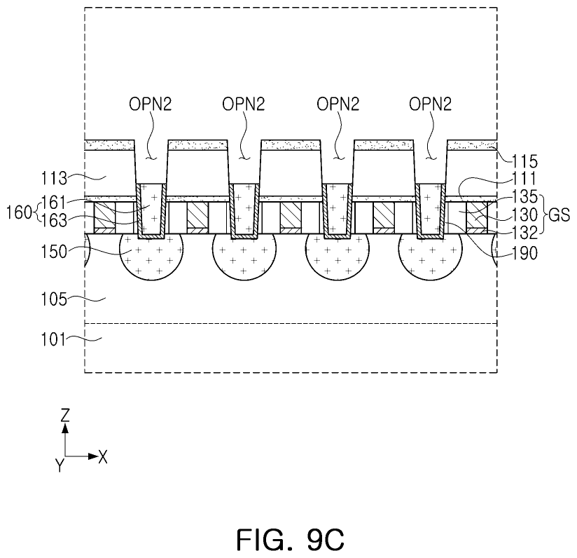

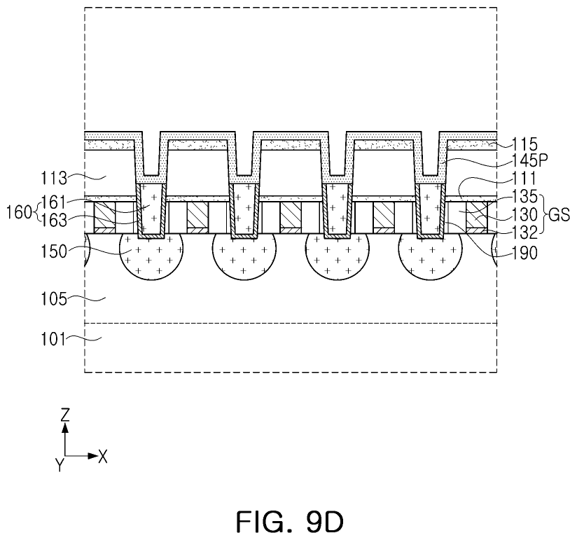

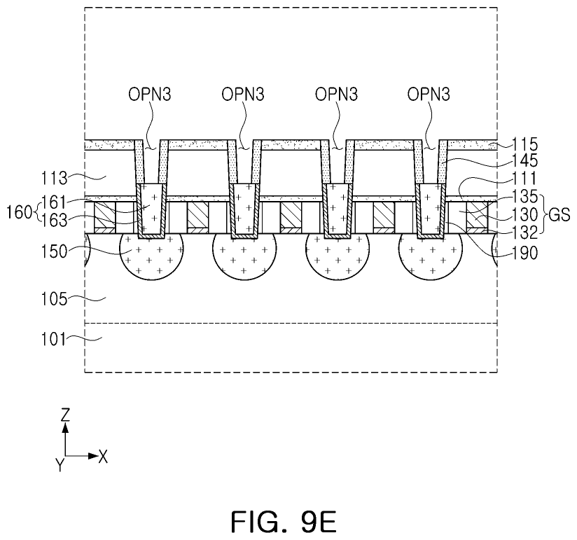

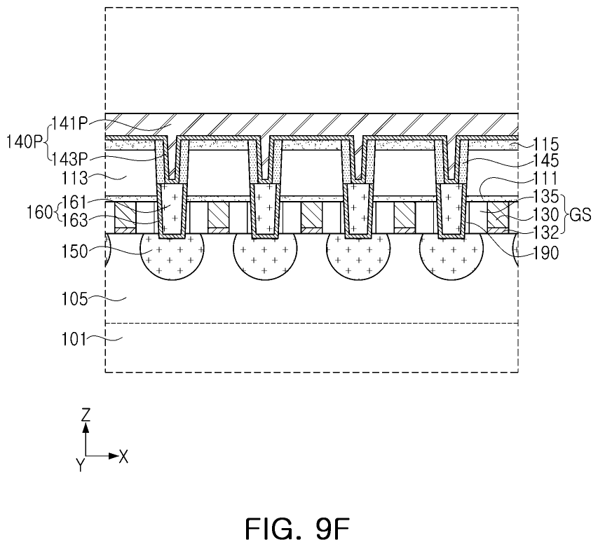

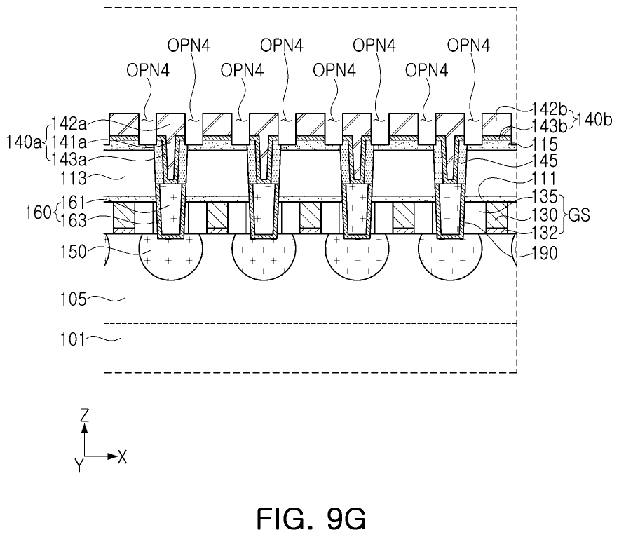

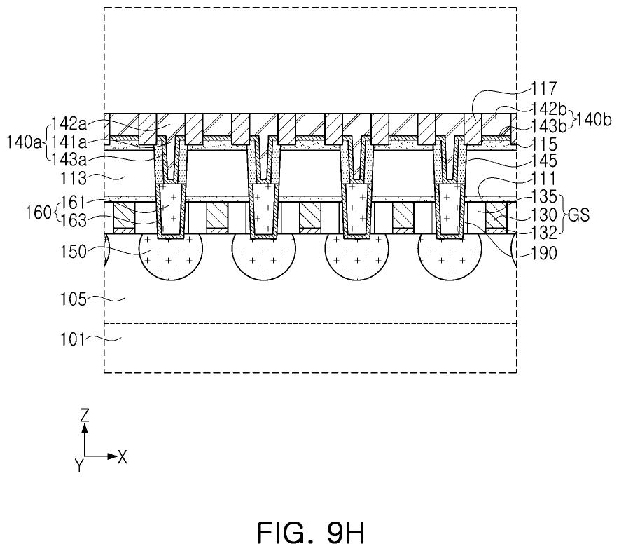

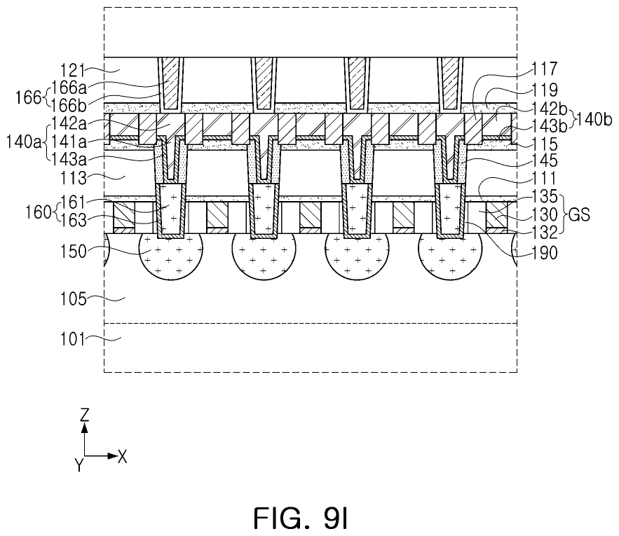

FIGS. 9A to 9I are diagrams illustrating a method of manufacturing a semiconductor device according to an example embodiment. The method of manufacturing a semiconductor device 1 in FIG. 6 may be described with reference to FIGS. 9A to 9I.

Referring to FIG. 9A, a method of manufacturing a semiconductor device may include forming active regions 105 by removing a portion of a substrate 101, forming gate structures GS on the active region 105, forming recess regions by removing a portion of the active region 105 exposed between the gate structures GS, and forming source/drain regions 150 in the recess regions, forming insulating structures 190 between the gate structures GS on the substrate 101, forming a first insulating liner 111, a first insulating layer 113, and a second insulating liner 115 in the vertical direction (Z-direction) in order on the gate structures GS and the insulating structures 190, and forming first contact holes OPN1 by removing a portion of each of the insulating structures 190, the first insulating liner 111, the first insulating layer 113, and the second insulating liner 115.

The forming the gate structures GS may include forming sacrificial gate structures (not illustrated), forming gate spacers 135 on a side surface of each of the sacrificial gate structures, removing the sacrificial gate structures, and forming a gate dielectric layer 132 and a gate electrode 130 in a region from which the sacrificial gate structures are removed.

The forming the first insulating liner 111, the first insulating layer 113, and the second insulating liner 115 may include forming the first insulating liner 111 on the gate structures GS and the insulating structures 190, forming the first insulating layer 113 on the first insulating liner 111, and forming the second insulating liner 115 on the first insulating layer 113 in order. The first insulating liner 111 and the second insulating liner 115 may include silicon nitride, and the first insulating layer 113 may include silicon oxide. A thickness in the vertical direction (Z-direction) of the first insulating layer 113 may be greater than each of thicknesses of the first and second insulating liners 111 and 115.

The first contact holes OPN1 may be formed by etching the second insulating liner 115, the first insulating layer 113, the first insulating liner 111 and the insulating structures 190 in order downwardly, and partially recessing the upper surface of the exposed source/drain regions 150.

Referring to FIG. 9B, first preliminary contact plugs 160P may be formed in the first contact holes OPN1. The forming the first preliminary contact plugs 160P may include conformally forming a first preliminary conductive barrier layer 163P according to a surface profile of the first contact holes OPN1, and forming a first preliminary conductive pattern 161P on the first preliminary conductive barrier layer 163P.

Referring to FIG. 9C, second contact holes OPN2 may be formed by removing a portion of each of the first preliminary contact plugs 160P. The forming the second contact holes OPN2 may include etching each of the first preliminary contact plugs 160P downwardly, and the side surface of the first insulating layer 113 and the side surface of the second insulating liner 115 may be exposed. First preliminary contact plugs 160P may be formed by removing a portion of each of the first insulating layer 113 and the second insulating liner 115, thereby forming first contact plugs 160 having an upper surface exposed from the side surfaces of the first insulating layer 113 and the second insulating liner 115.

Referring to FIG. 9D, first preliminary spacer layer 145P covering the upper surface of the second insulating liner 115 and the inner surface of the second contact holes OPN2 may be formed. The first preliminary spacer layer 145P may be formed conformally along the upper surface of the second insulating liner 115 and the inner surface of the second contact holes OPN2. The first preliminary spacer layer 145P may include at least one of oxide, nitride, and oxynitride.

Referring to FIG. 9E, third contact holes OPN3 exposing a portion of the upper surface of the first contact plugs 160 may be formed by removing the lower surface of the first preliminary spacer layer 145P formed in the second contact holes OPN2. The first contact spacer 145 may be conformally formed on the side surface of the third contact holes OPN3 on the first contact plugs 160. In the process of removing the lower surface of the first preliminary spacer layer 145P formed in the second contact holes OPN2, the first preliminary spacer layer 145P formed on the upper surface of the second insulating liner 115 may be removed together.

Referring to FIG. 9F, preliminary conductive structures 140P may be formed on the upper surface of the second insulating liner 115 and the inner surface of the third contact holes OPN3. The forming the preliminary conductive structure 140P may include forming a preliminary contact barrier layer 143P conformally according to a surface profile of the upper surface of the second insulating liner 115 and the inner surface of the third contact holes OPN3, and forming a preliminary contact conductive layer 141P on the preliminary contact barrier layer 143P. The preliminary contact barrier layer 143P may include metal nitride such as titanium nitride, tantalum nitride, and tungsten nitride, and the preliminary contact conductive layer 141P may include a metal material such as tungsten, aluminum, and copper.

Referring to FIG. 9G, by removing a portion of the preliminary conductive structure 140P formed on the second insulating liner 115 formed on the upper region between the first contact plugs 160, fourth openings OPN4 exposing the upper surface of the second insulating liner 115 may be formed.

First conductive structures 140a and second conductive structures 140b spaced apart from each other in the first direction (X-direction) and disposing alternately in the first direction (X-direction) may be formed by partially removing the preliminary conductive structure 140P. Each of the first conductive structures 140a may be electrically connected to the first contact plug 160, and each of the second conductive structures 140b may be connected to the second contact plug (e.g., the second contact plug 160g in FIG. 4)

In the process of partially removing the preliminary conductive structure 140P, a portion of the upper surface of the second insulating liner 115 formed below the preliminary conductive structure 140P may also be removed. The thickness of the second insulating liner 115 overlapping the first and second conductive structures 140a and 140b may be greater than the thickness of the second insulating liner 115 exposed through the fourth openings OPN4.

The first conductive structure 140a may include a first via portion 141a formed in the third contact holes OPN3 in FIG. 9E and surrounded by a first contact spacer 145, a first interconnection portion 142a formed on the second insulating liner 115 by extending from the first via portion 141a, and a first contact barrier layer 143a formed on the lower surface and the side surface of the first via portion 141a and the lower surface of the first interconnection portion 142a. The second conductive structure 140b may also be formed by a process similar to the process of forming the first conductive structure 140a.

Referring to FIG. 9H, the first insulating patterns 117 filling the fourth openings OPN4 may be formed. The first insulating patterns 117 may fill the fourth openings OPN4 exposing the upper surface of the second insulating liner 115 between the first interconnection portion 142a of the first conductive structure 140a and the second interconnection portion 142b of the second conductive structure 140b.

Referring to FIG. 9I, a third insulating liner 119 and a second insulating layer 121 may be formed in order on the first and second conductive structures 140a and 140b and the first insulating patterns 117, and third contact plugs 166 penetrating the third insulating liner 119 and the second insulating layer 121 and connected to the first conductive structures 140a may be formed.

The forming the third contact plugs 166 may include forming contact holes partially exposing an upper surface of the first conductive structures 140a by partially removing the third insulating liner 119 and the second insulating layer 121, conformally forming a third conductive barrier layer 166b in the contact holes, and forming a third conductive pattern 166a on the third conductive barrier layer 166b.

Thereafter, referring to FIGS. 3 and 6 together, second interconnection structures 171 and 173 (or the first interconnection structures 170 in FIG. 2C) may be formed on the third contact plugs 166, and the second interconnection structures 171 and 173 may be formed, a second bonding adhesive layer 109 may be formed on the lower surface of the substrate 101, and the second structure ST2 may be bonded to the pre-formed first structure ST1. After the first structure ST1 and the second structure ST2 are bonded to each other, a second through-plug 60 penetrating the second insulating layer 121, the first, second, third insulating liners 111, 115, and 119, the first insulating pattern 117, the first insulating layer 113, the insulating structure 190, the substrate 101 and the second bonding adhesive layer 109, and the first bonding adhesive layer 19 and the fifth insulating structure 15 of first structure ST1 and interconnected to at least one of the second interconnections 237 may be formed. After the second through-plug 60 is formed, interconnection structures (e.g., the second horizontal interconnections 176 and the first and second vertical vias 174 and 178, and the upper interconnection 180 in FIG. 3) are formed on the first horizontal interconnection 172 and the second interconnection structures 171 and 173, such that the semiconductor device 1 may be manufactured.

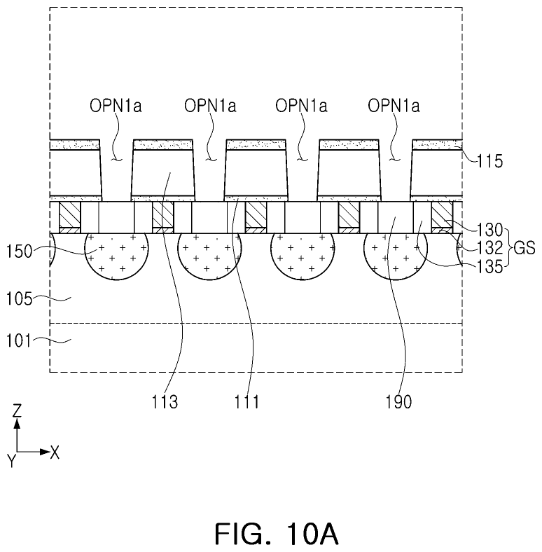

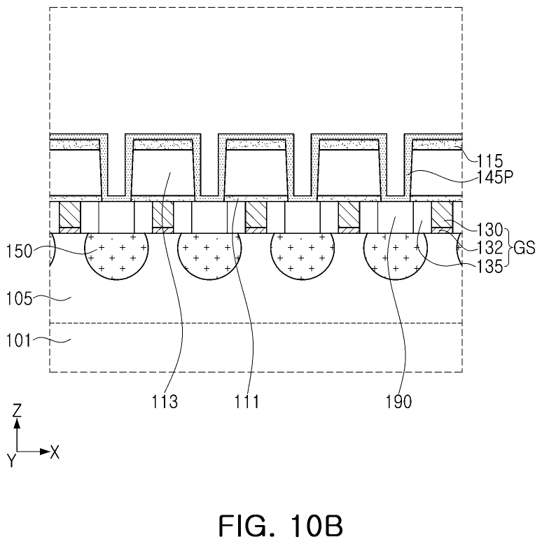

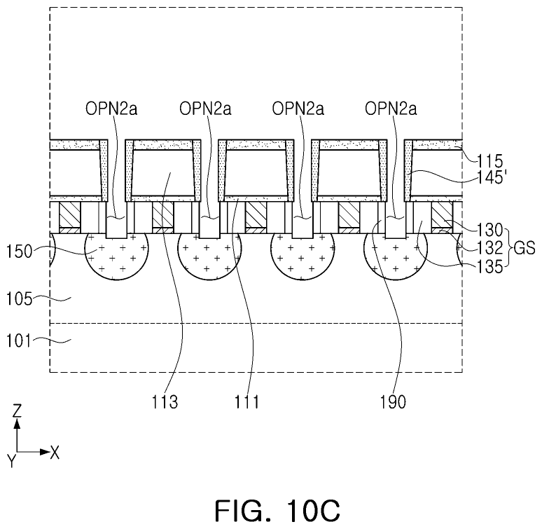

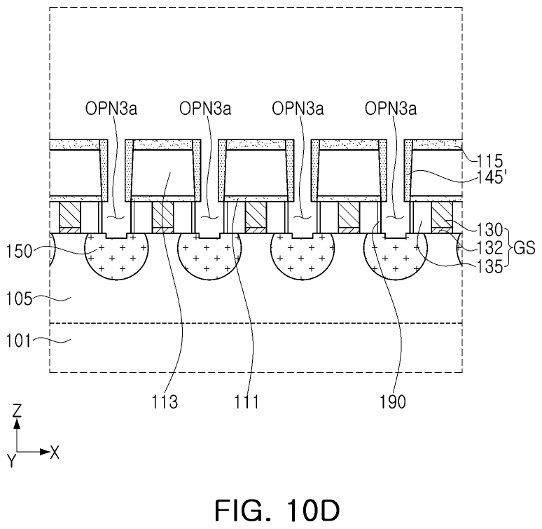

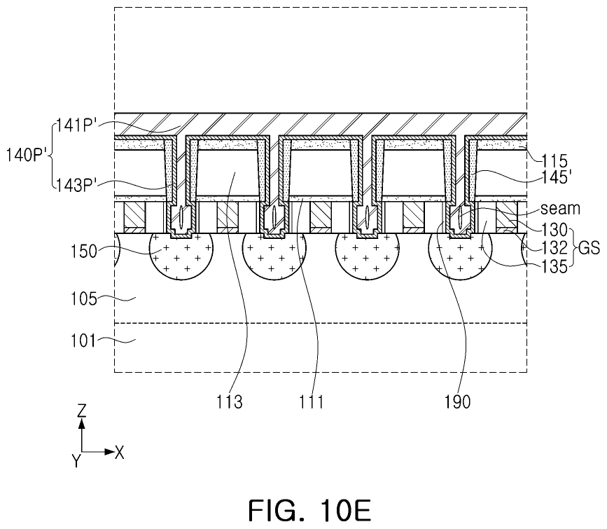

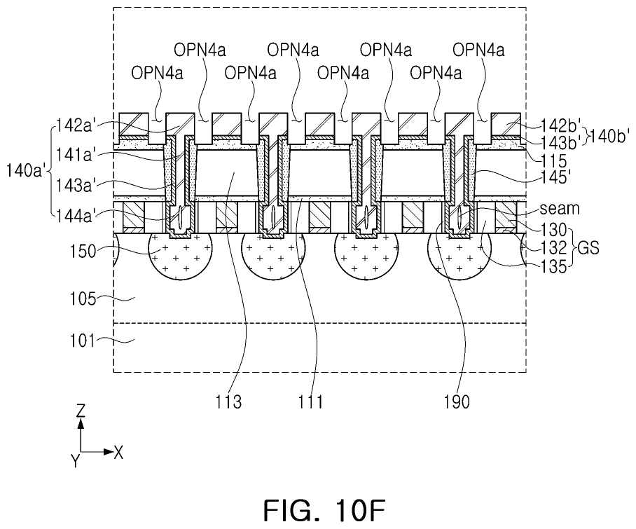

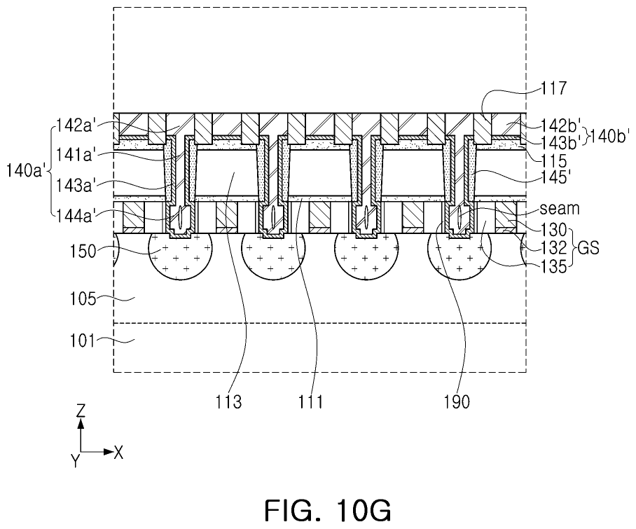

FIGS. 10A to 10G are diagrams illustrating a method of manufacturing a semiconductor device according to another example embodiment. A method of manufacturing a semiconductor device 1b in FIG. 8B may be described with reference to FIGS. 10A to 10G.

Referring to FIG. 10A, a method of manufacturing a semiconductor device may include forming active regions 105 by removing a portion of a substrate 101, forming gate structures GS on the active region 105, forming recess regions by removing a portion of the active region 105 exposed between the gate structures GS, and forming source/drain regions 150 in the recess regions, forming insulating structures 190 between the gate structures GS on the substrate 101, forming a first insulating liner 111, a first insulating layer 113, and a second insulating liner 115 in order in the vertical direction (Z-direction) on the gate structures GS and the insulating structures 190, and forming first contact holes OPN1a exposing an upper surface of the insulating structures 190 by removing a portion of each of the first insulating liner 111, the first insulating layer 113, and the second insulating liner 115.

The first contact holes OPN1a may be formed by etching the second insulating liner 115, the first insulating layer 113, and the first insulating liner 111 in order downwardly. The upper surface of the insulating structures 190 may be exposed through the first contact holes OPN1a.

Referring to FIG. 10B, the first preliminary spacer layer 145P covering the upper surface of the second insulating liner 115 and the inner surface of the first contact holes OPN1a may be formed. The first preliminary spacer layer 145P may be conformally formed along the upper surface of the second insulating liner 115 and the inner surface of the first contact holes OPN1a.

Referring to FIG. 10C, second contact holes OPN2a may be formed by removing the lower surface of the first preliminary spacer layer 145P formed in the first contact holes OPN1a and a portion of the insulating structures 190. The second contact holes OPN2a may be formed by etching the lower surface of the first preliminary spacer layer 145P and the insulating structures 190 overlapping the first preliminary spacer layer 145P and partially recessing the upper surface of the exposed source/drain regions 150.

The first contact spacer 145′ may be conformally formed on the side surface of the second contact holes OPN2a on the insulating structure 190. In the process of removing the lower surface of the first preliminary spacer layer 145P formed in the first contact holes OPN1a in FIG. 10A, the first preliminary spacer layer 145P formed on the upper surface of the second insulating liner 115 may be removed together.

Referring to FIG. 10D, third contact holes OPN3a may be formed by removing a portion of the side surface of the insulating structures 190 in the first direction (X-direction). The third contact holes OPN3a may be configured as extended contact holes extending in the first direction (X-direction) and exposing the side surface of the insulating structures 190. The first contact spacers 145′ may overlap the extended contact holes in the vertical direction (Z-direction). The thickness of each of the insulating structures 190 in FIG. 10D may be smaller than the thickness of each of the insulating structures 190 in FIG. 10C. The distance in the first direction (X-direction) between the side surfaces of the insulating structures 190 exposed through the third contact holes OPN3a may be greater than the distance between the first contact spacers 145′ opposing each other.

Referring to FIG. 10E, a preliminary conductive structure 140P′ may be formed on the upper surface of the second insulating liner 115 and the inner surface of the third contact holes OPN3a. The forming the preliminary conductive structure 140P′ may include conformally forming a preliminary contact barrier layer 143P′ according to a surface profile of the upper surface of the second insulating liner 115 and the inner surface of the third contact holes OPN3a, and forming a preliminary contact conductive layer 141P′ on the preliminary contact barrier layer 143P. A seam may be formed in the process of filling the preliminary contact conductive layer 141P′ in the expanded contact holes in FIG. 10D. The seam may be configured to extend in the vertical direction (Z-direction).

Referring to FIG. 10F, fourth openings OPN4a exposing the upper surface of the second insulating liner 115 may be formed by partially removing the preliminary conductive structure 140P′ formed on the second insulating liner 115 in the upper region between the third contact holes OPN3a in FIG. 10D.

First conductive structures 140a′ and second conductive structures 140b′ spaced apart from each other in the first direction (X-direction) and disposed alternately in the first direction (X-direction) may be formed by partially removing the preliminary conductive structure 140P′. Each of the first conductive structures 140a′ may be electrically connected to the source/drain region 150, and each of the second conductive structures 140b′ may be connected to the gate electrode 130.

The first conductive structure 140a′ may include a seam and may include a first lower region 144a′ in contact with the source/drain region 150, a first intermediate region 141a′ surrounded by the first contact spacer 145′ on the first lower region 144a′, a first upper region 142a′ extending from the first intermediate region 141a′ on the first intermediate region 141a′ and a first contact barrier layer 143a′ covering the side surface of the first intermediate region 141a′ and the lower surface of the first lower region 144a′.

Referring to FIG. 10G, the first insulating patterns 117 filling the fourth openings OPN4a may be formed. The first insulating patterns 117 may fill the fourth openings OPN4a exposing the upper surface of the second insulating liner 115 between the first upper region 142a′ of the first conductive structure 140a′ and the second upper region 142b′ of the second conductive structure 140b.

The operations described with reference to FIG. 9I may be applied in the same manner.

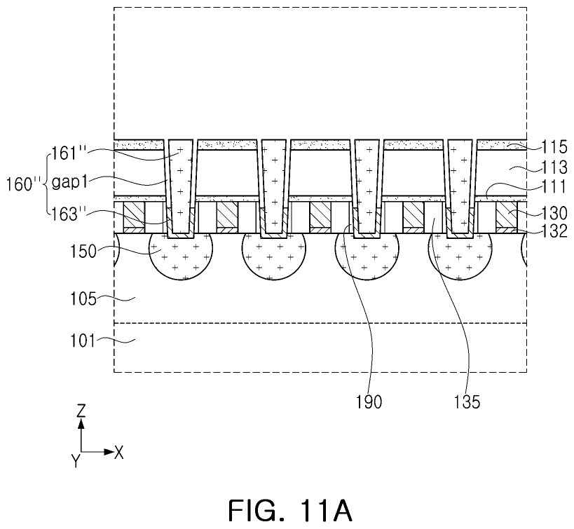

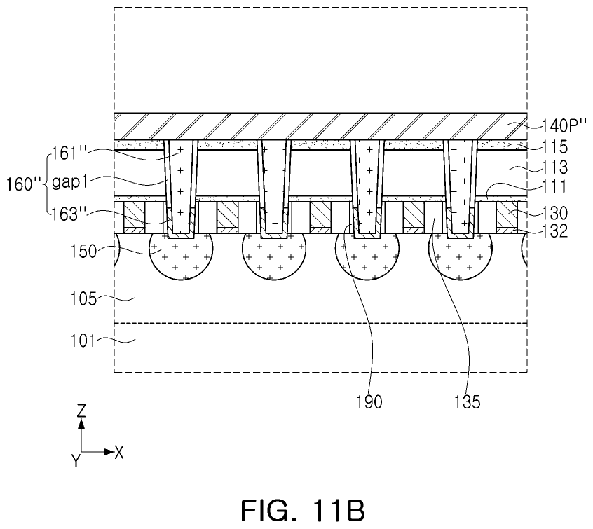

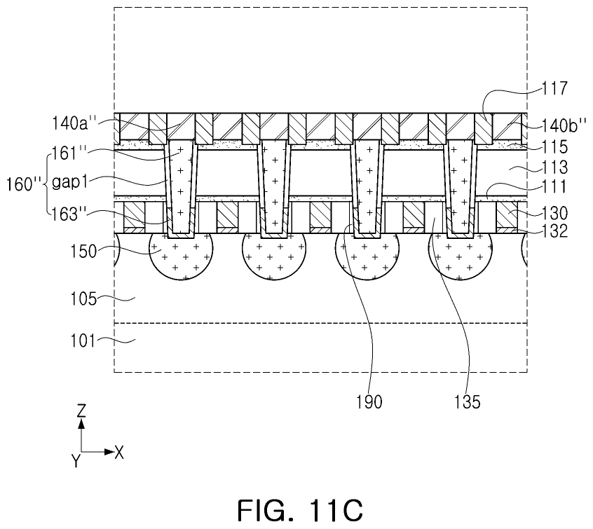

FIGS. 11A to 11C are diagrams illustrating a method of manufacturing a semiconductor device according to another example embodiment. A method of manufacturing a semiconductor device 1c in FIG. 8C may be described with reference to FIGS. 11A to 11C.

Referring to FIG. 11A together with FIGS. 9A and 9B, a method of manufacturing a semiconductor device may include forming active regions 105 by removing a portion of a substrate 101, forming gate structures GS on the active region 105, forming recess regions by removing a portion of the active region 105 exposed between the gate structures GS, forming source/drain regions 150 in the recess regions, forming insulating structures 190 between the gate structures GS on the substrate 101, forming a first insulating liner 111, a first insulating layer 113, and a second insulating liner 115 in order in the vertical direction (Z-direction) on the gate structures GS and the insulating structures 190, forming first contact holes OPN1 by removing a portion of each of the insulating structures 190, the first insulating liner 111, the first insulating layer 113, and the second insulating liner 115, forming first preliminary contact plugs 160P in the first contact holes OPN1, and forming first contact plugs 160″ including first gap region gap1 by removing a portion of the first preliminary conductive barrier layer 163P.

The first contact plug 160″ may include a first conductive pattern 161″, a first conductive barrier layer 163″ covering a portion of a lower surface and a side surface of the first conductive pattern 161″, and a first gap region gap1 exposing the other portion of the side surface of the first conductive pattern 161″.

The removing a portion of the first preliminary conductive barrier layer 163P in FIG. 9B may be a process of removing the first preliminary conductive barrier layer 163P between the first and second insulating liners 111, 115 and the first conductive pattern 161 and between the first insulating layer 113 and the first conductive pattern 161 through a dry or wet etching process. However, an example embodiment thereof is not limited thereto, and the level at which the first preliminary conductive barrier layer 163P is removed may be determined variously. A portion of the side surface of the first conductive pattern 161″ may be exposed through the first gap region gap1.

Referring to FIG. 11B, a preliminary conductive structure 140P″ may be formed on the second insulating liner 115 and the first contact plugs 160″. The preliminary conductive structure 140P″ may be formed as a single conductive layer. However, an example embodiment thereof is not limited thereto, and for example, the preliminary conductive structure 140P″ may be formed as a preliminary contact barrier layer and a preliminary conductive layer on the preliminary contact barrier layer on the second insulating liner 115 and the first contact plugs 160″.

Referring to FIG. 11C, openings exposing the upper surface of the second insulating liner 115 may be formed by removing a portion of the preliminary conductive structure 140P″ formed on the second insulating liner 115 formed on the upper region between the first contact plugs 160″, and the first insulating patterns 117 filling the openings may be formed. Subsequent process operations may be applied in the same manner as described with reference to FIG. 9I.

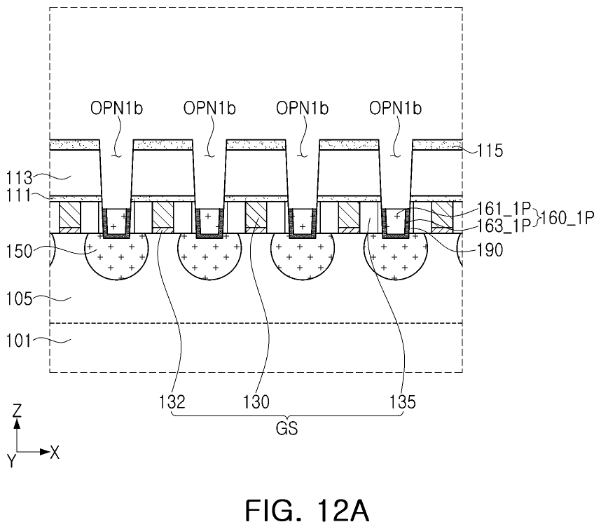

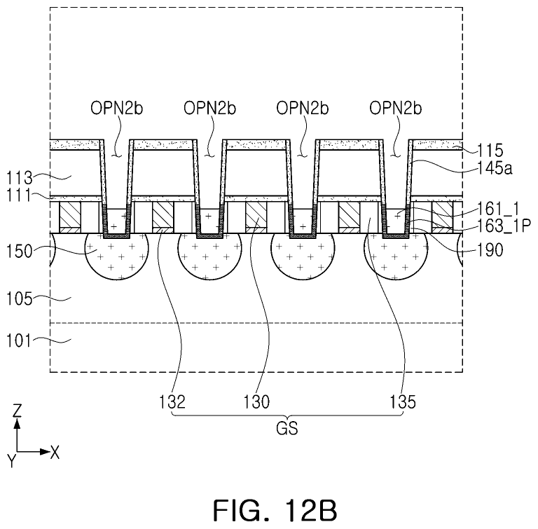

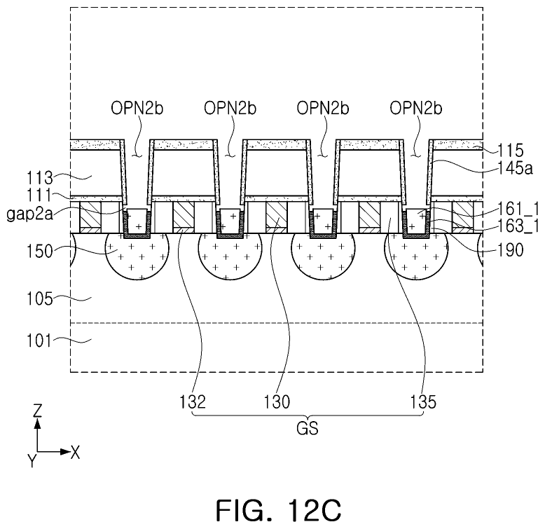

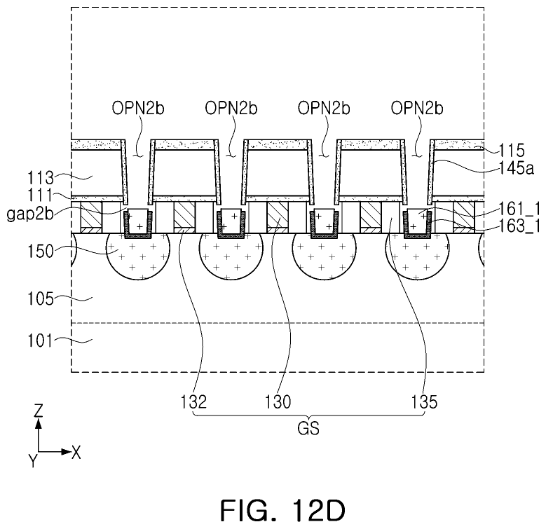

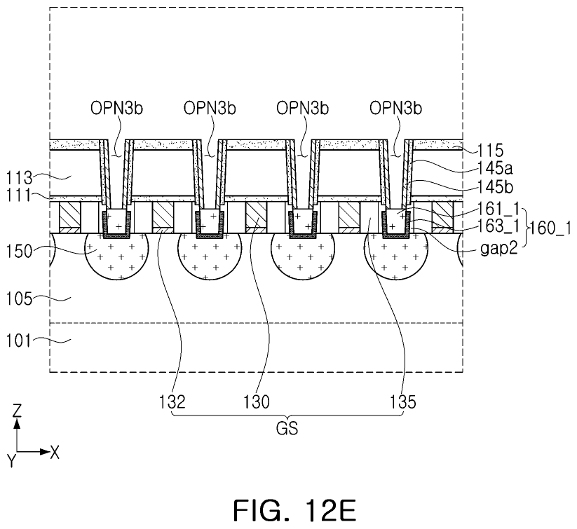

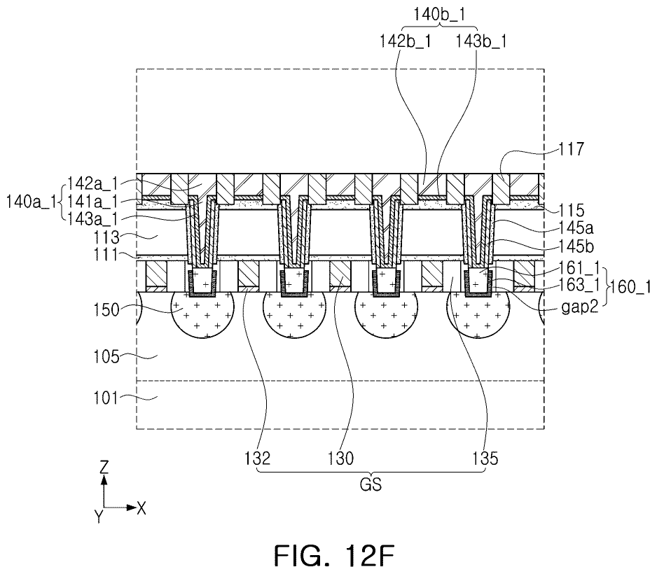

FIGS. 12A to 12F are diagrams illustrating a method of manufacturing a semiconductor device according to another example embodiment. A method of manufacturing a semiconductor device 1e in FIG. 8E may be described with reference to FIGS. 12A to 12F.

Referring to FIG. 12A together with FIGS. 9A and 9B, a method of manufacturing a semiconductor device may include forming active regions 105 by removing a portion of a substrate 101, forming gate structures GS on the active region 105, forming recess regions by removing a portion of the active region 105 exposed between the gate structures GS, forming source/drain regions 150 in the recess regions, forming insulating structures 190 between the gate structures GS on the substrate 101, forming a first insulating liner 111, a first insulating layer 113, and a second insulating liner 115 in order in the vertical direction (Z-direction) on the gate structures GS and the insulating structures 190, forming first contact holes OPN1 by removing a portion of each of the insulating structures 190, the first insulating liner 111, the first insulating layer 113, and the second insulating liner 115, forming first preliminary contact plugs 160P in the first contact holes OPN1, and forming first contact holes OPN1b by removing a portion of each of the first preliminary contact plugs 160P.

The forming the first contact holes OPN1b may include etching each of the first preliminary contact plugs 160P downwardly to have a level lower than a level of the first insulating liner 111. A side surface of the second insulating liner 115, a side surface of the first insulating layer 113, and a side surface of the first insulating liner 111 may be exposed through the first contact holes OPN1b. A side surface of an upper region of the insulating structures 190 may be exposed through the first contact holes OPN1b. By etching each of the first preliminary contact plugs 160P to have a level lower than a level of the first insulating liner 111, first preliminary contact plugs 160_1P may be formed. The first preliminary contact plugs 160_1P may include a first preliminary conductive pattern 161_1P disposed below the first insulating liner 111 and a first preliminary conductive barrier layer 163_1P covering the lower surface and the side surface of the first preliminary conductive pattern 161_1P.

Referring to FIG. 12B, the 1-1 contact spacer 145a may be formed, and the second contact holes OPN2b exposing the upper surface of the recessed first conductive pattern 161_1 may be formed.

The forming the 1-1 contact spacer 145a may include conformally forming the first preliminary contact spacer layer on the internal side surface of the first contact holes OPN1b in FIG. 12A, and removing the lower surface of the first preliminary contact spacer layer on the internal side surface of the first contact holes OPN1b. The forming the second contact holes OPN2b may include partially exposing the side surface of the first preliminary conductive barrier layer 163_1P by recessing a portion of the upper surface of the first preliminary conductive pattern 161_1P overlapping the first preliminary contact spacer layer. By recessing a portion of the upper surface of the first preliminary conductive pattern 161_1P, the first conductive pattern 161_1 may be formed.

Referring to FIG. 12C, a first gap portion gap2a may be formed by removing a portion of the side surface of the first preliminary conductive barrier layer 163_1P exposed through the second contact holes OPN2b. A portion of the side surface of the insulating structure 190 may be exposed through the first gap portion gap2a. A first conductive barrier layer 163_1 may be formed by removing a portion of the side surface of the first preliminary conductive barrier layer 163_1P.

Referring to FIG. 12D, a second gap portion gap2b may be formed by removing a portion of the side surface of the insulating structure 190 exposed through the first gap portion gap2a. A gate spacer 135 may be exposed through the second gap portion gap2b. The insulating structure 190 may be a material having etching selectivity higher than that of the gate spacer 135.

Referring to FIG. 12E, a 1-2 contact spacer 145b may be formed on the side surface of the 1-1 contact spacer 145a exposed through the second contact holes OPN2b.

The forming the 1-2 contact spacer 145b may include forming a second contact spacer layer (not illustrated) on the internal side surface of the 1-1 contact spacer 145a exposed through the second contact holes OPN2b, removing the lower surface of the second contact spacer layer disposed on the first conductive pattern 161_1, and forming third contact holes OPN3b exposing the upper surface of the first conductive pattern 161_1.

The lower surface of the 1-2 contact spacer 145b may be in contact with the upper surface of the first conductive pattern 161_1. The lower surface of the 1-2 contact spacer 145b may be disposed at a level lower than a level of the lower surface of the 1-1 contact spacer 145a. By forming the 1-2 contact spacer 145b, a second gap region gap2 surrounding the side surface of the first conductive pattern 161_1 and the side surface of the first conductive barrier layer 163_1 may be defined. Accordingly, a first contact plug 160_1 including the second gap region gap2 may be formed.

Referring to FIG. 12F, a first conductive structure 140a_1 including a first via portion 141a_1, a first interconnection portion 142a_1 extending from the first via portion 141a_1 on the first via portion 141a_1, and a first contact barrier layer 143a_1 covering a lower surface and a side surface of the first via portion 141a_1 and the lower surface of the first interconnection portion 142a_1, and a second conductive structure 140b_1 disposed alternately with the first conductive structure 140a_1 may be formed, and first insulating patterns 117 disposed between the first conductive structure 140a_1 and the second conductive structure 140b_1 may be formed.

The forming the first conductive structure 140a_1 and the second conductive structure 140b_1 may include forming a preliminary conductive structure (not illustrated) in the upper surface of the second insulating liner 115 and the third contact holes OPN3b, and removing a portion region of the preliminary conductive structure. The preliminary conductive structure may include a preliminary contact barrier layer and a preliminary contact conductive layer formed on the preliminary contact barrier layer.

The process operation described with reference to FIG. 9I may be applied in the same manner.

According to the aforementioned example embodiments, the semiconductor device may include a contact plug connected to a source/drain region of a peripheral transistor, a conductive structure on the contact plug, and a contact spacer surrounding a contact via of the conductive structure between the contact plug and the contact interconnection of the conductive structure. Accordingly, bridging between the contact interconnection of the conductive structure and another adjacent conductive structure or bridging between a contact via of the conductive structure and a contact interconnection of another conductive structure adjacent to the conductive structure may be reduced or prevented, thereby providing a semiconductor device having improved reliability.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described herein could be termed a second element, component, region, layer or section, without departing from the spirit and scope of the present disclosure.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Components or layers described with reference to being “sequential” or “sequentially stacked” in a particular direction or manner may be at layered, adjoined, proximate, orientated, or otherwise arranged with respect to each other to achieve the illustrated or contemplated relativity, optionally with other components, layers, etc. therebetween. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device

It will be understood that when an element is referred to as being “on” or “disposed on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.). The term “connected” may be used herein to refer to a physical and/or electrical connection.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a first structure comprising a memory region; and
a second structure vertically overlapping the first structure and comprising a peripheral circuit region vertically overlapping the memory region;
wherein the first structure comprises:
memory cells in the memory region, the memory cells respectively comprising a vertical channel transistor and a data storage structure; and
a cell routing interconnection structure connected to the memory cells,
wherein the second structure comprises:
a peripheral transistor comprising a gate structure and a source/drain region;
a first contact plug on and connected to the source/drain region; and
a first conductive structure on and connected to the first contact plug,
wherein the first conductive structure comprises a first via portion in contact with the first contact plug, and a first interconnection portion on and extending from the first via portion; and
wherein a width in a first direction of the first via portion is smaller than a width in the first direction of the first interconnection portion.

2. The semiconductor device of claim 1, further comprising:
a first contact spacer between the first contact plug and the first interconnection portion of the first conductive structure and on a side surface of the first via portion.

3. The semiconductor device of claim 1, further comprising:
a second contact plug on and connected to the gate structure;
a second conductive structure on and connected to the second contact plug and spaced apart from the first conductive structure in the first direction; and
wherein the second conductive structure comprises a second via portion in contact with the gate structure, and a second interconnection portion on and extending from the second via portion.

4. The semiconductor device of claim 3, wherein the second conductive structure further comprises a second contact spacer between the second contact plug and the second interconnection portion of the second conductive structure, and extending along a side surface of the second via portion.

5. The semiconductor device of claim 3, wherein an upper surface of the first conductive structure is coplanar with an upper surface of the second conductive structure.

6. The semiconductor device of claim 3, wherein a lower surface of the first via portion of the first conductive structure is coplanar with a lower surface of the second via portion of the second conductive structure.

7. The semiconductor device of claim 1, wherein:
the first contact plug comprises a first conductive pattern and a first conductive barrier layer extending along a side surface and a lower surface of the first conductive pattern; and
the first conductive structure further comprises a first contact barrier layer on a side surface and a lower surface of the first via portion and a lower surface of the first interconnection portion.

8. The semiconductor device of claim 1, further comprising:
a first insulating liner on the gate structure of the peripheral transistor;
a first insulating layer on the first insulating liner; and
a second insulating liner on the first insulating layer,
wherein the first interconnection portion of the first conductive structure is on the second insulating liner, and the first via portion of the first conductive structure penetrates the second insulating liner,
wherein the first and second insulating liners comprise a first insulating material, and
wherein the first insulating layer comprises a second insulating material different from the first insulating material.

9. The semiconductor device of claim 8, wherein an upper surface of the first contact plug and a lower surface of the first via portion of the first conductive structure are between a lower surface and an upper surface of the first insulating layer.

10. The semiconductor device of claim 8, wherein:
the first via portion of the first conductive structure penetrates the first insulating liner and the first insulating layer; and
an upper surface of the first contact plug is confined below the first insulating liner.

11. The semiconductor device of claim 8, further comprising:
a first contact spacer between the first contact plug and the first interconnection portion of the first conductive structure and on a side surface of the first via portion; and
an insulating pattern on the second insulating liner,
wherein a side surface of the first contact spacer is in contact with the first insulating layer, the second insulating liner, and the insulating pattern.

12. The semiconductor device of claim 1, wherein a width in the first direction of an upper surface of the first contact plug is greater than a width in the first direction of a lower surface of the first via portion of the first conductive structure.

13. A semiconductor device, comprising:
a substrate comprising an active region extending in a first direction;
a gate structure extending in a second direction intersecting the active region on the substrate;
a source/drain region in a recessed region of the active region on at least one side of the gate structure;
a first conductive structure on and connected to the source/drain region; and
a first contact spacer,
wherein the first conductive structure comprises a first interconnection portion, a first via portion extending from a lower surface of the first interconnection portion, and a first contact barrier layer on a lower surface of the first interconnection portion and a side surface and a lower surface of the first via portion, and
wherein the first contact spacer extends along at least a portion of the side surface of the first via portion below the first interconnection portion, relative to the substrate.

14. The semiconductor device of claim 13, further comprising:
a second conductive structure electrically on and connected to the gate structure and spaced apart from the first conductive structure in the first direction; and
wherein the second conductive structure comprises a second interconnection portion, a second via portion extending from a lower surface of the second interconnection portion, and a second contact barrier layer on a lower surface of the second interconnection portion and a side surface and a lower surface of the second via portion.

15. The semiconductor device of claim 14, further comprising:
a second contact spacer extending along the side surface of the second via portion below the second interconnection portion, relative to the substrate.

16. The semiconductor device of claim 13, wherein a width in the first direction of the first via portion is smaller than a width in the second direction of the first via portion.

17. The semiconductor device of claim 13,
wherein the first via portion of the first conductive structure comprises a first portion in contact with the source/drain region and a second portion on and extending from the first portion, and
wherein a width in the first direction of the first portion is greater than a width in the first direction of the second portion, and the first contact spacer extends along a side surface of the second portion.

18. The semiconductor device of claim 13, further comprising:
a first contact plug between the source/drain region and the first via portion of the first conductive structure, and comprising a conductive pattern and a conductive barrier layer extending along a side surface and a lower surface of the conductive pattern,
wherein the first contact spacer overlaps the first contact plug in a vertical direction intersecting the first direction and the second direction.

19. The semiconductor device of claim 13, further comprising:
a dummy gate structure spaced apart from the gate structure in the second direction on the substrate,
wherein the first interconnection portion of the first conductive structure comprises a first extension portion overlapping the source/drain region in a vertical direction intersecting the first and second directions and extending in the second direction, a bent portion extending from the first extension portion to a region between the gate structure and the dummy gate structure, and a second extension portion overlapping the dummy gate structure in the vertical direction and extending in the second direction.

20. A semiconductor device, comprising:
a first structure having a memory region; and
a second structure vertically overlapping the first structure and comprising a peripheral circuit region vertically overlapping the memory region,
wherein the first structure comprises:
memory cells in the memory region, the memory cells respectively comprising a vertical channel transistor and a data storage structure; and
a cell routing interconnection structure connected to the memory cells,
wherein the second structure comprises:
a substrate comprising an active region extending in a first direction;
a peripheral gate structure extending in a second direction intersecting the active region on the substrate;
a source/drain region in a recessed region of the active region on at least one side of the peripheral gate structure;
a first contact plug on and connected to the source/drain region;
a second contact plug on and connected to the peripheral gate structure;
a first conductive structure on and connected to the first contact plug;
a second conductive structure on and connected to the second contact plug;
a first contact spacer; and
a second contact spacer,
wherein the first conductive structure comprises a first via portion in contact with the first contact plug, and a first interconnection portion on and extending from the first via portion in the second direction;
wherein the second conductive structure comprises a second via portion in contact with the second contact plug, and a second interconnection portion on and extending from the second via portion in the second direction and spaced apart from the first interconnection portion in the first direction;
wherein the first contact spacer is between the first contact plug and the first interconnection portion of the first conductive structure and is on a side surface of the first via portion, and
wherein the second contact spacer is between the second contact plug and the second interconnection portion of the second conductive structure and is on a side surface of the second via portion.
